(19) United States
(12) Patent Application Publication
(10) Pub. No.: US 2024/0413247 A1
(43) Pub. Date: Dec. 12, 2024

(54) COMPOSITIONALLY-MODULATED CAPPING LAYER FOR A TRANSISTOR AND METHODS FOR FORMING THE SAME

(71) Applicant: Taiwan Semiconductor Manufacturing Company Limited, Hsinchu (TW)

(72) Inventors: Kuo-Chang Chiang, Hsinchu (TW); Katherine H. Chiang, New Taipei City (TW); Yen-Chung Ho, Hsinchu (TW); Ming-Yen Chuang, Hsinchu City (TW); Chung-Te Lin, Taiwan City (TW)

(21) Appl. No.: 18/329,606

(22) Filed: Jun. 6, 2023

(51) Int. Cl. H01L 29/786; H01L 21/4757; H01L 29/66; H10B 61/00; H10B 63/00

(52) U.S. Cl. CPC H01L 29/78618; H01L 21/47576; H01L 29/66969; H01L 29/7869; H10B 61/22; H10B 63/30

(57) ABSTRACT

A reduced interfacial defect density and low contact resistance can be provided for a thin film transistor by using a compositionally-modulated capping layer. A stack including a gate electrode, a gate dielectric layer, an active layer including a semiconducting metal oxide material, an in-process capping layer including a dielectric metal oxide material can be formed over a substrate. A dielectric material layer can be formed, and a source cavity and a drain cavity can be formed through the dielectric material layer. Exposed portions of the in-process capping layer can be converted into conductive material portions to provide a compositionally-modulated capping layer, which includes a first conductive capping material portion, the second conductive capping material portion, and a dielectric capping material portion.

### BACKGROUND

Transistors made of oxide semiconductors are an attractive option for back-end-of-line (BEOL) integration since they may be processed at low temperatures and thus, will not damage previously fabricated devices. For example, the fabrication conditions and techniques do not damage previously fabricated front-end-of-line (FEOL) and middle end-of-line (MEOL) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary structure after formation of complementary metal-oxide-semiconductor (CMOS) transistors, first metal interconnect structures formed in lower-level dielectric layers, an insulating material layer, and an optional etch stop dielectric layer according to an embodiment of the present disclosure.

FIGS. 2A-2C are various views of a region of an intermediate structure after formation of a gate contact via structure according to an embodiment of the present disclosure. FIGS. 2A is a top-down view, FIG. 2B is a vertical cross-sectional view along the vertical plane B-B′ of FIGS. 2A and 2C, and FIG. 2C is a vertical cross-sectional view along the vertical plane C-C′ of FIG. 2A and 2B.

FIGS. 3A-3C are various views of a region of the intermediate structure after formation of a continuous gate electrode material layer, a continuous gate dielectric material layer, a continuous semiconducting material layer, and a continuous metal layer according to an embodiment of the present disclosure. FIGS. 3A is a top-down view, FIG. 3B is a vertical cross-sectional view along the vertical plane B-B′ of FIGS. 3A and 3C, and FIG. 3C is a vertical cross-sectional view along the vertical plane C-C′ of FIG. 3A and 3B.

FIGS. 4A-4C are various views of a region of the intermediate structure after conversion of the continuous metal layer into a continuous capping material layer according to an embodiment of the present disclosure. FIGS. 4A is a top-down view, FIG. 4B is a vertical cross-sectional view along the vertical plane B-B′ of FIGS. 4A and 4C, and FIG. 4C is a vertical cross-sectional view along the vertical plane C-C′ of FIG. 4A and 4B.

FIGS. 5A-5C are various views of a region of the intermediate structure after formation of a continuous insulating cap layer according to an embodiment of the present disclosure. FIGS. 5A is a top-down view, FIG. 5B is a vertical cross-sectional view along the vertical plane B-B′ of FIGS. 5A and 5C, and FIG. 5C is a vertical cross-sectional view along the vertical plane C-C′ of FIG. 5A and 5B.

FIGS. 6A-6C are various views of a region of the intermediate structure after forming a layer stack including a gate electrode, a gate dielectric layer, an active layer, an in-process capping layer, and an insulating cap layer according to an embodiment of the present disclosure. FIGS. 6A is a top-down view, FIG. 6B is a vertical cross-sectional view along the vertical plane B-B′ of FIGS. 6A and 6C, and FIG. 6C is a vertical cross-sectional view along the vertical plane C-C′ of FIG. 6A and 6B.

FIGS. 7A-7C are various views of a region of the intermediate structure after formation of a dielectric material layer according to an embodiment of the present disclosure. FIGS. 7A is a top-down view, FIG. 7B is a vertical cross-sectional view along the vertical plane B-B′ of FIGS. 7A and 7C, and FIG. 7C is a vertical cross-sectional view along the vertical plane C-C′ of FIG. 7A and 7B.

FIGS. 8A-8C are various views of a region of the intermediate structure after formation of a source cavity and a drain cavity according to an embodiment of the present disclosure. FIGS. 8A is a top-down view, FIG. 8B is a vertical cross-sectional view along the vertical plane B-B′ of FIGS. 8A and 8C, and FIG. 8C is a vertical cross-sectional view along the vertical plane C-C′ of FIG. 8A and 8B.

FIGS. 9A-9C are various views of a region of a first configuration of the intermediate structure after formation of conductive capping material portions according to an embodiment of the present disclosure. FIGS. 9A is a top-down view, FIG. 9B is a vertical cross-sectional view along the vertical plane B-B′ of FIGS. 9A and 9C, and FIG. 9C is a vertical cross-sectional view along the vertical plane C-C′ of FIG. 9A and 9B.

FIGS. 10A-10C are various views of a region of the first configuration of the embodiment structure after formation of a source structure and a drain structure according to an embodiment of the present disclosure. FIGS. 10A is a top-down view, FIG. 10B is a vertical cross-sectional view along the vertical plane B-B′ of FIGS. 10A and 10C, and FIG. 10C is a vertical cross-sectional view along the vertical plane C-C′ of FIG. 10A and 10B.

FIGS. 11A-11C are various views of a region of a second configuration of the embodiment structure after formation of conductive capping material portions according to an embodiment of the present disclosure. FIGS. 11A is a top-down view, FIG. 11B is a vertical cross-sectional view along the vertical plane B-B′ of FIGS. 11A and 11C, and FIG. 11C is a vertical cross-sectional view along the vertical plane C-C′ of FIG. 11A and 11B.

FIGS. 12A-12C are various views of a region of the second configuration of the embodiment structure after formation of a source structure and a drain structure according to an embodiment of the present disclosure. FIGS. 12A is a top-down view, FIG. 12B is a vertical cross-sectional view along the vertical plane B-B′ of FIGS. 12A and 12C, and FIG. 12C is a vertical cross-sectional view along the vertical plane C-C′ of FIG. 12A and 12B.

FIGS. 13A-13C are various views of a region of a third configuration of the embodiment structure after formation of conductive capping material portions according to an embodiment of the present disclosure. FIGS. 13A is a top-down view, FIG. 13B is a vertical cross-sectional view along the vertical plane B-B′ of FIGS. 13A and 13C, and FIG. 13C is a vertical cross-sectional view along the vertical plane C-C′ of FIG. 13A and 13B.

FIGS. 14A-14C are various views of a region of the third configuration of the embodiment structure after formation of a source structure and a drain structure according to an embodiment of the present disclosure. FIGS. 14A is a top-down view, FIG. 14B is a vertical cross-sectional view along the vertical plane B-B′ of FIGS. 14A and 14C, and FIG. 14C is a vertical cross-sectional view along the vertical plane C-C′ of FIG. 14A and 14B.

FIG. 15 is a vertical cross-sectional view of the exemplary structure after formation of optional additional embodiment transistors and other structures over the complementary metal-oxide-semiconductor (CMOS) transistors, first metal interconnect structures formed in lower-level dielectric layers, and an insulating material layer of FIG. 1.

FIG. 16 is a first flowchart that illustrates the general processing steps for manufacturing the semiconductor devices of the present disclosure.

FIG. 17 is a second flowchart that illustrates the general processing steps for manufacturing the semiconductor devices of the present disclosure.

FIG. 18 is a third flowchart that illustrates the general processing steps for manufacturing the semiconductor devices of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

Current flow in a semiconducting metal oxide material is affected by the concentration of charge carriers and surface defect density, i.e., interface trap density Dᵢₜ. As the channel length decreases, the short channel effect and back channel leakage current adversely impacts current-voltage characteristics of transistors, and in particular thin-film transistors. Further, high contact resistance between source/drain structures and a semiconductor channel material can degrade the on-current and the reliability of the transistor.

Generally, surfaces of a semiconducting metal oxide material are susceptible to formation of various types of electronic and structural defects, which may occur during a film deposition, gas treatment, plasma treatment, and/or impurity diffusion such as diffusion of hydrogen, oxygen, water vapor, and/or metallic impurities. In instances in which such defects are formed on the backside (opposite side) of a gate electrode, a back channel layer including defects as trap centers can be formed. Such defects may cause leakage current. In a negative bias operation, electrons may be trapped in the back channel layer. These trapped electrons may provide a short channel leakage path. This leakage path may induce an initial uncontrolled negative threshold voltage (Vt) shift, and can degrade negative bias stress instability (NBTI). Reducing the charge carrier concentration in a semiconducting metal oxide material in order to reduce electron trapping can result in a low on-current with a large positive threshold voltage shift.

According to an aspect of the present disclosure, an active layer including a semiconducting metal oxide material may be formed as a main semiconducting channel of a transistor (i.e., thin-film transistor). An in-process capping layer including a dielectric metal oxide material may be formed on the active layer. The dielectric metal oxide material can be selected from materials that can reduce the interface trap density at an interface with a subsequently deposited insulating cap layer. In other words, an interface between the dielectric metal oxide material with the dielectric material of the insulating cap layer may be configured to provide a lower interface trap density than an interface between the semiconducting metal oxide material with the dielectric material of the insulating cap layer. The dielectric metal oxide material can have a similar banding gap (which may be in a range from 2.5 eV to 3.5 eV) as the semiconducting metal oxide material. Further portions of the in-process capping layer that are exposed to a source cavity or a drain cavity are converted into conductive material portions. The dielectric metal oxide material includes a material that may be reduced, upon loss of oxygen atoms, into at least one metal, or may be converted into a conductive metal-rich non-stoichiometric metal oxide material upon ion implantation with at least one metallic element. Thus, a compositionally-modulated capping layer can be formed, which provides low contact resistance for the source structure and the drain structure, and reduces the interfacial trap density on the backside (i.e., the side that is distal from a gate electrode) of a semiconducting channel, and thus, reduces the leakage current and improves the transistor characteristics.

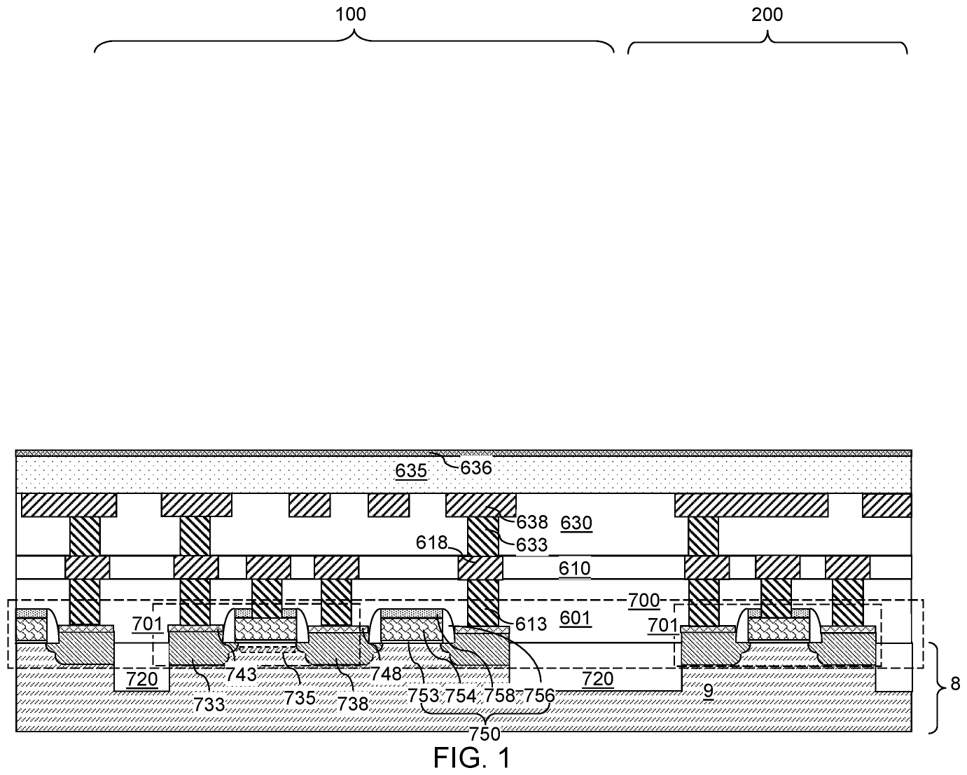

Referring to FIG. 1, an exemplary structure according to an embodiment of the present disclosure is illustrated. The exemplary structure includes a substrate 8. Generally, the substrate 8 comprises, and/or consists essentially of, at least one material selected from an insulating material, a semiconductor material, and a metallic material. In one embodiment, the substrate 8 may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material. The first structure may include a memory region 100 and a logic region 200.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source electrode 733, a drain electrode 738, a semiconductor channel 735 that includes a surface portion of the substrate 8 extending between the source electrode 733 and the drain electrode 738, and a gate structure 750. The semiconductor channel 735 may include a single crystalline semiconductor material. Each gate structure 750 may include a gate dielectric layer 753, a gate electrode 754, a gate cap dielectric 758, and a dielectric gate spacer 756. A source-side metal-semiconductor alloy region 743 may be formed on each source electrode 733, and a drain-side metal-semiconductor alloy region 748 may be formed on each drain electrode 738.

One or more of the field effect transistors 701 in the CMOS circuitry 700 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel. In one embodiment, a plurality of field effect transistors 701 in the CMOS circuitry 700 may include a respective node that is subsequently electrically connected to a node of a respective ferroelectric memory cell to be subsequently formed. For example, a plurality of field effect transistors 701 in the CMOS circuitry 700 may include a respective source electrode 733 or a respective drain electrode 738 that is subsequently electrically connected to a node of a respective ferroelectric memory cell to be subsequently formed.

In one embodiment, the substrate 8 may include a single crystalline silicon substrate, and the field effect transistors 701 may include a respective portion of the single crystalline silicon substrate as a semiconducting channel. As used herein, a “semiconducting” element may refer to an element having electrical conductivity in the range from 1.0×10⁻⁶ S/cm to 1.0×10⁵ S/cm. As used herein, a “semiconductor material” may refer to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, a dielectric material or an insulating material refers to a material having electrical conductivity less than 1.0×10⁻⁶ S/cm. All measurements are taken at the standard condition, i.e., at 0 degrees Celsius and at 1 atmospheric pressure.

Various metal interconnect structures formed within dielectric layers may be subsequently formed over the substrate 8 and the semiconductor devices thereupon (such as field effect transistors 701). In an illustrative example, the dielectric layers may include, for example, a first dielectric layer 601 that may be a layer that surrounds the contact structure connected to the source and drains (sometimes referred to as a contact-level dielectric layer 601), a first interconnect-level dielectric layer 610, and a second interconnect-level dielectric layer 630. The metal interconnect structures may include device contact via structures 613 formed in the first dielectric layer 601 and contact a respective component of the CMOS circuitry 700, first metal line structures 618 formed in the first interconnect-level dielectric layer 610, first metal via structures 633 formed in a lower portion of the second interconnect-level dielectric layer 630, and second metal line structures 638 formed in an upper portion of the second interconnect-level dielectric layer 630.

Each of the dielectric layers (601, 610, 630) may include a dielectric material such as undoped silicate glass, a doped silicate glass, organosilicate glass, amorphous fluorinated carbon, porous variants thereof, or combinations thereof. Each of the metal interconnect structures (613, 618, 633, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 633 and the second metal line structures 638 may be formed as integrated line and via structures by a dual damascene process. The dielectric layers (601, 610, 630) are herein referred to as lower-lower-level dielectric layers. The metal interconnect structures (613, 618, 633, 638) formed within in the lower-level dielectric layers are herein referred to as lower-level metal interconnect structures.

While the present disclosure is described using an embodiment wherein transistors, such as thin film transistors, may be formed over the second interconnect-level dielectric layer 630, other embodiments are expressly contemplated herein in which the array of memory cells may be formed at a different metal interconnect level. Further, while the present disclosure is described using an embodiment in which a semiconductor substrate is used as the substrate 8, embodiments are expressly contemplated herein in which an insulating substrate or a conductive substrate is used as the substrate 8.

The set of all dielectric layer that are formed prior to formation of an array of transistors (e.g., thin-film transistors, TFTs) or an array of memory cells (e.g., ferroelectric memory cells) is collectively referred to as lower-level dielectric layers (601, 610, 630). The set of all metal interconnect structures that is formed within the lower-level dielectric layers (601, 610, 630) is herein referred to as metal interconnect structures (613, 618, 633, 638). Generally, metal interconnect structures (613, 618, 633, 638) formed within at least one lower-level dielectric layer (601, 610, 630) may be formed over the semiconductor material layer 9 that is located in the substrate 8.

According to an aspect of the present disclosure, a transistor, such as thin film transistors (TFTs) may be subsequently formed in a metal interconnect level that overlies that metal interconnect levels that contain the lower-level dielectric layers (601, 610, 630) and the metal interconnect structures (613, 618, 633, 638). In one embodiment, a planar dielectric layer having a uniform thickness may be formed over the lower-level dielectric layers (601, 610, 630). The planar dielectric layer is herein referred to as an insulating material layer 635. The insulating material layer 635 includes a dielectric material such as undoped silicate glass, a doped silicate glass, organosilicate glass, or a porous dielectric material, and may be deposited by chemical vapor deposition. The thickness of the insulating material layer 635 may be in a range from 30 nm to 300 nm, although lesser and greater thicknesses may also be used.

Generally, interconnect-level dielectric layers (such as the lower-level dielectric layer (601, 610, 630)) containing therein the metal interconnect structures (such as the metal interconnect structures (613, 618, 633, 638)) may be formed over semiconductor devices. The insulating material layer 635 may be formed over the interconnect-level dielectric layers.

In one embodiment, the substrate 8 may include a single crystalline silicon substrate, and lower-level dielectric layers (601, 610, 630) embedding lower-level metal interconnect structures (613, 618, 633, 638) may be located above the single crystalline silicon substrate. Field effect transistors 701 including a respective portion of the single crystalline silicon substrate as a channel may be embedded within the lower-level dielectric layers (601, 610, 630). The field effect transistors may be subsequently electrically connected to at least one of a gate electrode, a source electrode, and a drain electrode of one or more, or each, of transistors, such as thin film transistors, to be subsequently formed.

An etch stop dielectric layer 636 may be optionally formed over the insulating material layer 635. The etch stop dielectric layer 636 includes an etch stop dielectric material providing higher etch resistance to an etch chemistry during a subsequently anisotropic etch process that etches a dielectric material to be subsequently deposited over the etch stop dielectric layer 636. For example, the etch stop dielectric layer 636 may include silicon carbide nitride, silicon nitride, silicon oxynitride, or a dielectric metal oxide such as aluminum oxide. The thickness of the etch stop dielectric layer 636 may be in a range from 3 nm to 40 nm, such as from 4 nm to 30 nm, although lesser and greater thicknesses may also be used.

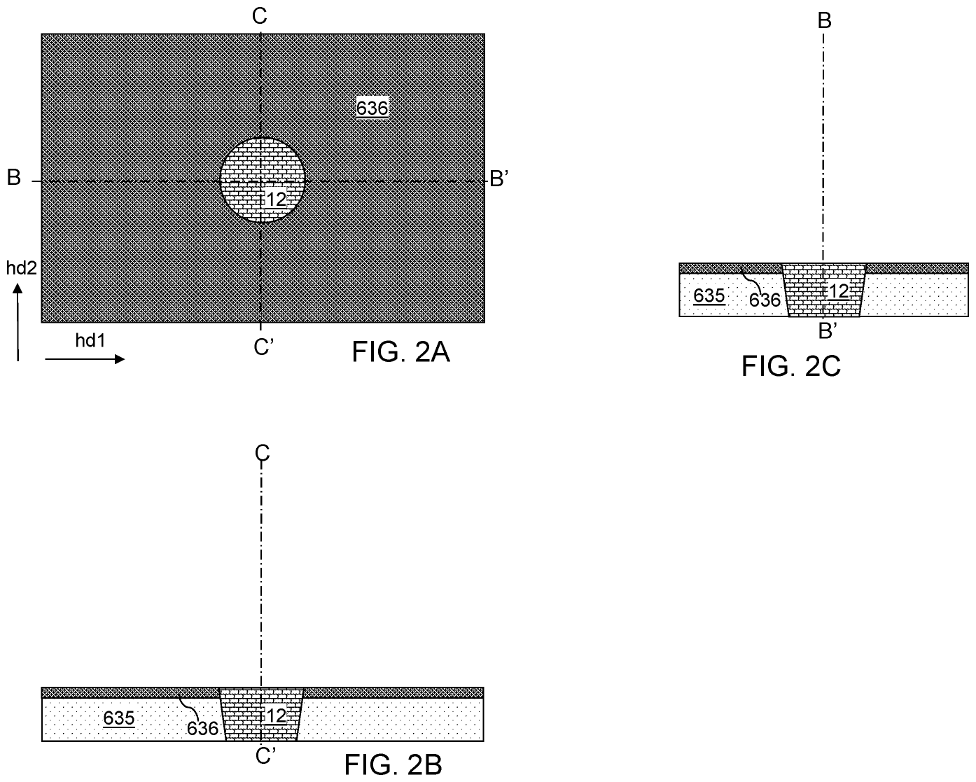

Referring to FIGS. 2A-2C, a region of the intermediate structure for forming a transistor (e.g., thin film transistor) is illustrated after formation of a gate contact via structure 12. For example, a via cavity may be formed through the etch stop dielectric layer 636 and the insulating layer 635 on a respective one of the underlying metal interconnect structures (not illustrated in FIGS. 2A-2C), and at least one metallic material may be deposited in the via cavity. Excess portions of the at least one metallic material may be removed from above the horizontal plane including the top surface of the etch stop dielectric layer 636 by a planarization process such as a chemical mechanical planarization process. A remaining portion of the at least one metallic material constitutes the gate contact via structure 12.

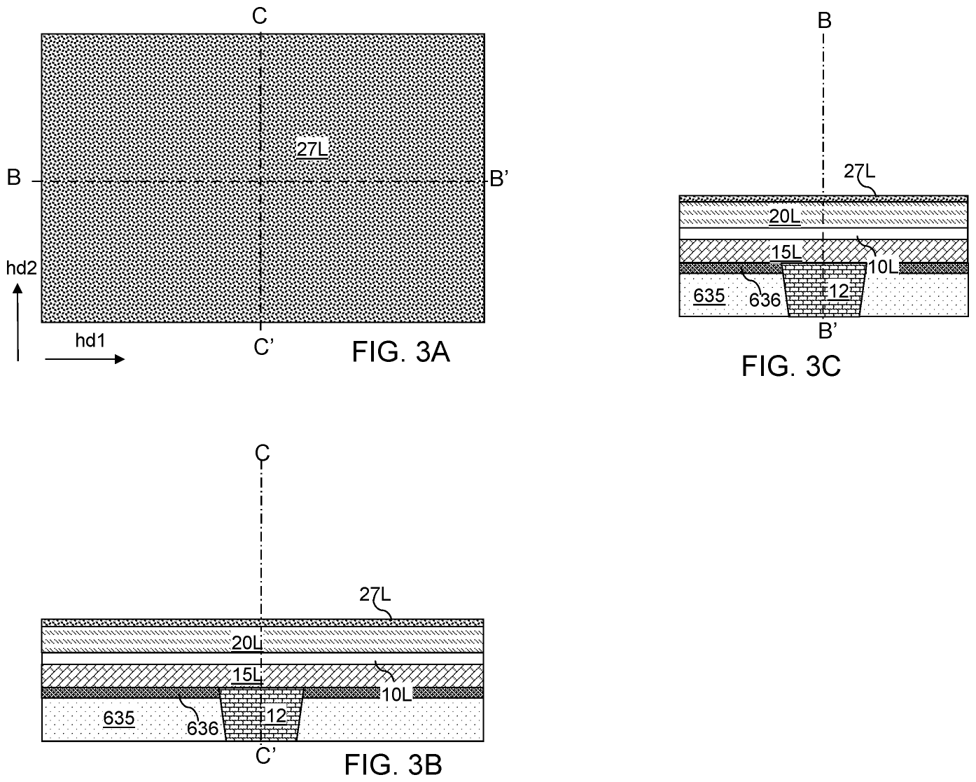

Referring to FIGS. 3A-3C, a continuous gate electrode material layer 15L, a continuous gate dielectric material layer 10L, a continuous semiconducting material layer 20L, and a continuous metal layer 27L may be sequentially deposited over the etch stop dielectric layer 636.

The continuous gate electrode material layer 15L comprises at least one conductive gate electrode material. The at least one conductive gate electrode material may include, for example, a metallic barrier liner material (such as TiN, TaN, and/or WN) and a metallic fill material (such as Cu, W, Mo, Co, Ru, etc.). Other suitable metallic barrier liner and metallic fill materials are within the contemplated scope of disclosure. The continuous gate electrode material layer 15L may be deposited by chemical vapor deposition or physical vapor deposition. The thickness of the continuous gate electrode material layer 15L may be in a range from 20 nm to 200 nm, although lesser and greater thicknesses may also be used.

The continuous gate dielectric material layer 10L may be formed over the continuous gate electrode material layer 15L. The continuous gate dielectric material layer 10L may include, but is not limited to, silicon oxide, silicon oxynitride, silicon nitride, a dielectric metal oxide (such as aluminum oxide, hafnium oxide, yttrium oxide, zirconium oxide, lanthanum oxide, etc.), or a stack thereof. Other suitable dielectric materials are within the contemplated scope of disclosure. In a non-limiting illustrative example, the continuous gate dielectric material layer 10 may comprise, and/or may consist essentially of at least one dielectric metal oxide material (such as aluminum oxide, hafnium oxide, titanium oxide, tantalum oxide, lanthanum oxide, hafnium silicate, etc.), silicon oxide, silicon nitride, an ONO stack, a ferroelectric material layer, or other memory material layers known in the art. The continuous gate dielectric material layer 10L may be deposited by atomic layer deposition (ALD) or chemical vapor deposition (CVD). The thickness of the continuous gate dielectric material layer 10L may be in a range from 1 nm to 13 nm, such as from 3 nm to 6 nm, although lesser and greater thicknesses may also be used.

In one embodiment, the continuous semiconducting material layer 20L includes a semiconducting metal oxide material. The continuous semiconducting material layer 20L may be an un-patterned (i.e., blanket) semiconductor material layer. In one embodiment, the continuous semiconducting material layer 20L may comprise a compound semiconductor material. In one embodiment, the semiconducting material includes a material providing electrical conductivity in a range from 1.0 S/m to 1.0×10⁵ S/m upon suitable doping with electrical dopants (which may be p-type dopants or n-type dopants). Exemplary semiconducting materials that may be used for the continuous semiconducting material layer 20L include, but are not limited to, indium gallium zinc oxide (IGZO), indium tungsten oxide, indium zinc oxide, indium tin oxide, gallium oxide, indium oxide, doped zinc oxide, doped indium oxide, doped cadmium oxide, and various other doped variants derived therefrom. Generally, the continuous semiconducting material layer 20L may comprise oxides of at least one metal, such as at least two metals and/or at least three metals, selected from In, Zn, Ga, Sn, Pb, Zr, Sr, Ru, Mn, Mg, Nb, Ta, Hf, Al, La, Sc, Ti, V, Cr, Mo, W, Fe, Co, Ni, Pd, Ir, Ag, and any combination of the above. In an non-limiting example, the continuous semiconducting material layer 20L may have a composition of InₓGa_{y}Zn_{z}MₐO_{w}, in which M can be at least one metal selected from Ti, Al, Ag, W, Ce, Sn, V, and Sc; 0<x<1; 0≤y≤1; 0≤z≤1; 0≤a≤0.5; and 1≤w≤1.5. The value of w may be selected such that the continuous semiconducting material layer 20L is stoichiometric or near stoichiometric. Some of the metal elements may be present at a dopant concentration, e.g., at an atomic percentage less than 1.0%. Other suitable semiconducting materials are within the contemplated scope of disclosure. In one embodiment, the semiconducting material of the continuous semiconducting material layer 20L may include indium gallium zinc oxide.

In one embodiment, the continuous semiconducting material layer 20L comprises, and/or consists essentially of, a semiconducting metal oxide material having a first enthalpy of oxide formation. The continuous semiconducting material layer 20L may include a polycrystalline semiconducting material, or an amorphous semiconducting material that may be subsequently annealed into a polycrystalline semiconducting material having a greater average grain size. The continuous semiconducting material layer 20L may be deposited by physical vapor deposition although other suitable deposition processes may be used. The thickness of the continuous semiconducting material layer 20L may be in a range from 2 nm to 50 nm, such as from 3 nm to 30 nm and/or from 4 nm to 15 nm, although lesser and greater thicknesses may also be used.

The continuous metal layer 27L may be formed by deposition of at least one metal that can be subsequently converted into a dielectric metal oxide material having a second enthalpy of formation that is greater than the first enthalpy of formation of the semiconducting metal oxide material of the continuous semiconducting material layer 20L. In embodiments in which the continuous metal layer 27L comprises at least two metals, the alloy of the at least two metals may have a second enthalpy of formation that is greater than the first enthalpy of formation of the semiconducting metal oxide material of the continuous semiconducting material layer 20L. The thickness of the continuous metal layer 27L may be in a range from 0.1 nm to 1.5 nm. The thickness of the continuous metal layer 27L may be greater than 0.1 nm, and/or greater than 0.2 nm, and/or greater than 0.3 nm, and/or greater than 0.5 nm, and/or greater than 0.7 nm, and/or greater than 1.0 nm, and/or greater than 1.2 nm. Further, the thickness of the continuous metal layer 27L may be less than 1.5 nm, and/or less than 1.2 nm, and/or less than 1.0 nm, and/or less than 0.7 nm, and/or less than 0.5 nm, and/or less than 0.3 nm, and/or less than 0.2 nm.

The at least one metal of the continuous metal layer 27L may be selected such that a dielectric metal oxide material that is subsequently formed by oxidation of the at least one metal has a similar band gap as the semiconducting metal oxide material of the continuous semiconducting material layer 20L. In one embodiment, the at least one metal of the continuous metal layer 27L may be selected such that the dielectric metal oxide material that is subsequently formed by oxidation of the at least one metal has a higher dissolution bonding energy than the semiconducting metal oxide material of the continuous semiconducting material layer 20L. In one embodiment, the at least one metal of the continuous metal layer 27L can be selected such that the dielectric metal oxide material that is subsequently formed by oxidation of the at least one metal has a higher dissolution bonding energy than InO or ZnO. Generally, the at least one metal of the continuous metal layer 27L may comprise, and/or may consist of, one or more transition metals that satisfy the above requirement. In one embodiment, the at least one metal of the continuous metal layer 27L may comprise, and/or may consist essentially of, one or more of Ti, Ba, Ta, W, Mo, Hf, Y, La, etc.

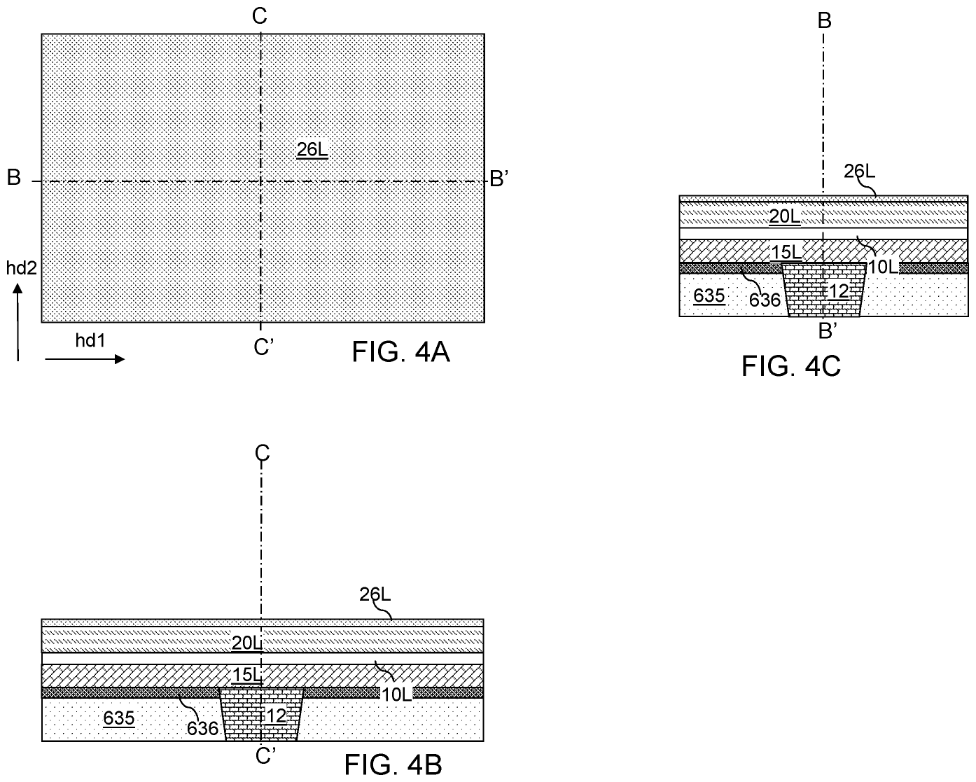

Referring to FIGS. 4A-4C, an oxidation process may be performed to convert the continuous metal layer 27L into a semiconducting metal oxide layer consisting of a dielectric metal oxide material. This semiconducting metal oxide layer functions as a capping layer for the continuous semiconducting material layer 20L, and is herein referred to as a continuous capping material layer 26L. The oxidation process may comprise a plasma oxidation process and/or a thermal oxidation process. The continuous capping material layer 26L comprises, and/or consists essentially of, an oxide of the at least one metal of the continuous metal layer. In one embodiment, the continuous capping material layer 26L may comprise, and/or may consist essentially of, titanium oxide, barium oxide, tantalum oxide, tungsten oxide, molybdenum oxide, hafnium oxide, yttrium oxide, lanthanum oxide, another transition metal oxide, or an alloy thereof.

The duration of the oxidation process may be selected such that the entirety of the continuous metal layer 27L is converted into the continuous capping material layer 26L. The thickness of the continuous capping material layer 26L may be in a range from 0.1 nm to 2.0 nm. The thickness of the continuous capping material layer 26L may be greater than 0.1 nm, and/or greater than 0.2 nm, and/or greater than 0.3 nm, and/or greater than 0.5 nm, and/or greater than 0.7 nm, and/or greater than 1.0 nm, and/or greater than 1.2 nm, and/or greater than 1.5 nm. Further, the thickness of the continuous capping material layer 26L may be less than 2.0 nm, and/or less than 1.5 nm, and/or less than 1.2 nm, and/or less than 1.0 nm, and/or less than 0.7 nm, and/or less than 0.5 nm, and/or less than 0.3 nm, and/or less than 0.2 nm. The ratio of the thickness of the continuous capping material layer 26L to the thickness of the continuous semiconducting material layer 20L may be in a range from 0.005 to 0.5, such as from 0.01 to 0.25, and/or from 0.02 to 0.1.

In one embodiment, the semiconducting metal oxide material of the continuous semiconducting material layer 20L may have a first enthalpy of formation, and the dielectric metal oxide material of the continuous capping material layer 26L may have a second enthalpy of formation that is greater than the first enthalpy of formation. In one embodiment, the dielectric metal oxide material of the continuous capping material layer 26L may have a greater thermal stability in a temperature range above 400 degrees Celsius than InO, ZnO, and the semiconducting metal oxide material of the continuous semiconducting material layer 20L.

Generally, the dielectric metal oxide material of the continuous capping material layer 26L may have a band gap that is about the same as the band gap of the semiconducting metal oxide material of the continuous semiconducting material layer 20L. For example, both the semiconducting metal oxide material of the continuous semiconducting material layer 20L and the dielectric metal oxide material of the continuous capping material layer 26L may have band gaps in a range from 2.5 eV to 3.5 eV. Thus, the stack of the continuous semiconducting material layer 20L and the continuous capping material layer 26L can function as a heterojunction semiconductor structure in which the continuous semiconducting material layer 20L functions as a main channel material, and the continuous capping material layer 26L functions as a back channel surface layer controlling the magnitude of the back channel current.

In one embodiment, the dielectric metal oxide material of the continuous capping material layer 26L provides a lower interface defect density than the semiconducting metal oxide material of the continuous semiconducting material layer 20L. In an illustrative example, the semiconducting metal oxide material of the continuous semiconducting material layer 20L may provide an interface defect density that is greater than 5×10¹¹/(cm²×eV) at an interface with a silicon oxide material, and the dielectric metal oxide material of the continuous capping material layer 26L may provide an interface defect density that is in a range from 1×10¹¹/(cm²×eV) to 5×10¹¹/(cm²×eV) at an interface with a silicon oxide material. Generally, the dielectric metal oxide material of the continuous capping material layer 26L can provide an interfacial trap density that is less than 5×10¹¹/(cm²×eV) at an interface with an overlying insulating material.

The threshold voltage shift through use of the dielectric metal oxide material of the continuous capping material layer 26L as a back channel material in a transistor may suppress shift in the threshold voltage during operation of the transistor. For example, it is estimated that the threshold voltage shift in a thin film transistor using the dielectric metal oxide material of the continuous capping material layer 26L is less than 200 mV after operation of the thin film transistor for 1.0×10⁶ seconds.

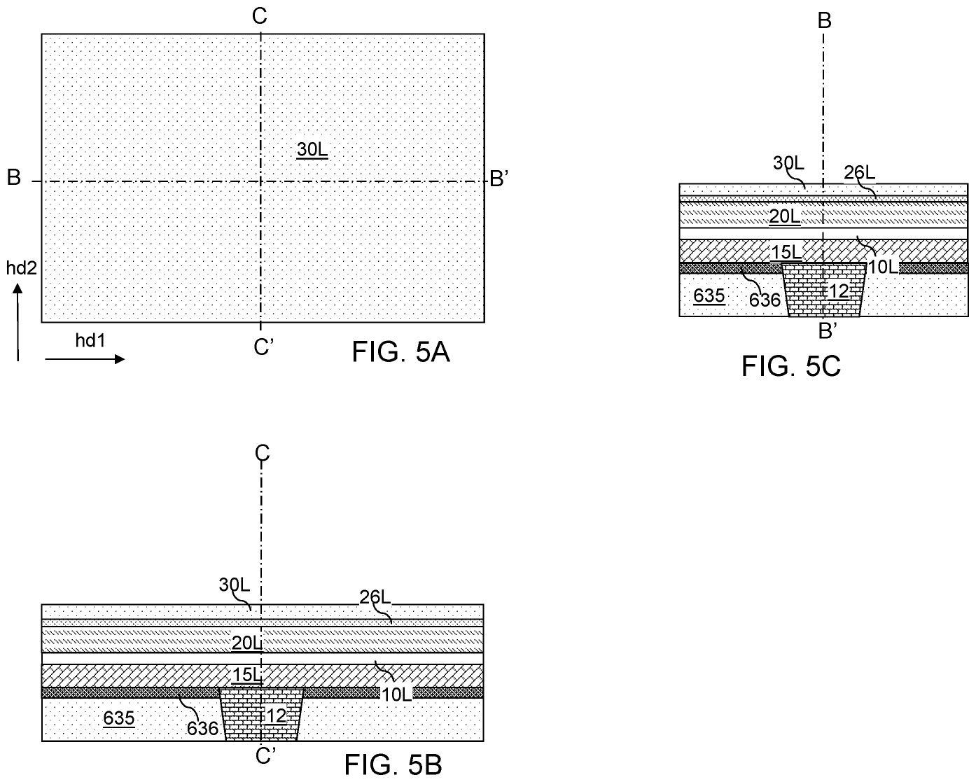

Referring to FIGS. 5A-5C, a continuous insulating cap layer 30L may be optionally deposited over the continuous capping material layer 26L. The continuous insulating cap layer 30L includes an insulating material such as silicon oxide, silicon nitride, silicon oxynitride, or silicon carbide nitride. The continuous insulating cap layer 30L may be deposited by a chemical vapor deposition process. The thickness of the continuous insulating cap layer 30L may be in a range from 2 nm to 30 nm, such as from 4 nm to 15 nm, although lesser and greater thicknesses may also be used.

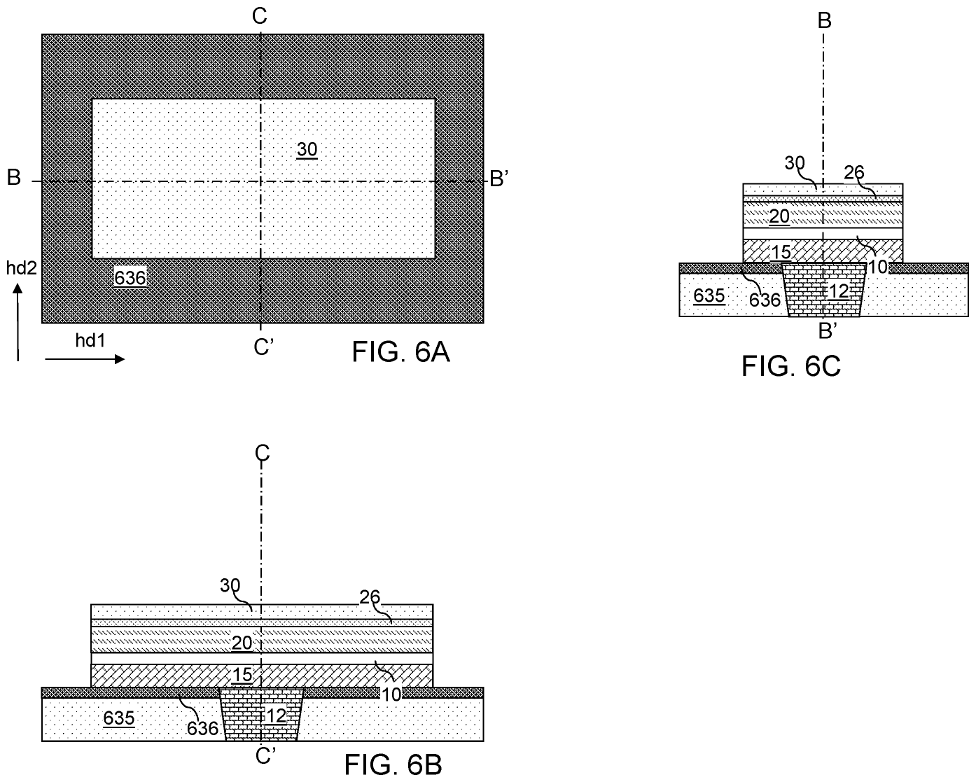

Referring to FIGS. 6A-6C, a photoresist layer (not shown) may be applied over the continuous insulating cap layer 30L, and may be lithographically patterned to form at least one discrete photoresist material portion, such as a two-dimensional array of discrete photoresist material portions. An anisotropic etch process may be performed to etch unmasked portions of the continuous insulating cap layer 30L, continuous capping material layer 26L, the continuous semiconducting material layer 20L, the continuous gate dielectric material layer 10L, and the continuous gate electrode material layer 15L. Each patterned portion of the continuous insulating cap layer 30L comprises an insulating cap layer 30. Each patterned portion of the continuous capping material layer 26L comprises an in-process capping layer 26. Each patterned portion of the continuous semiconducting material layer 20L comprises a active layer 20, which is an active layer including an oxide of a binary metal alloy. Each patterned portion of the continuous gate dielectric material layer 10L comprises a gate dielectric layer 10. Each patterned portion of the continuous gate electrode material layer 15L comprise a gate electrode 15. As used herein, an “in-process” element refers to an element that is subsequently modified either in shape or in material composition.

Each vertical stack of a gate electrode 15, a gate dielectric layer 10, an active layer 20, an in-process capping layer 26, and an insulating cap layer 30 may have vertically coincident sidewalls, i.e., sidewalls that are located within a same vertical plane. Each stack of a gate electrode 15 and a gate dielectric layer 10 is herein referred to a gate stack (15, 10). The photoresist layer may be subsequently removed, for example, by ashing or dissolved by solution.

In one embodiment, each layer within a vertical stack of a gate electrode 15, a gate dielectric layer 10, an active layer 20, an in-process capping layer 26, and an insulating cap layer 30 may have a same area in a plan view (such as a see-through top-down view) along a vertical direction that is perpendicular to the interface between the active layer 20 and the gate dielectric layer 10. In one embodiment, the gate electrode 15 laterally extends horizontally with a uniform gate electrode thickness, and has a same area as the active layer 20, the gate dielectric layer 10, the in-process capping layer 26, and the insulating cap layer 30 in the plan view.

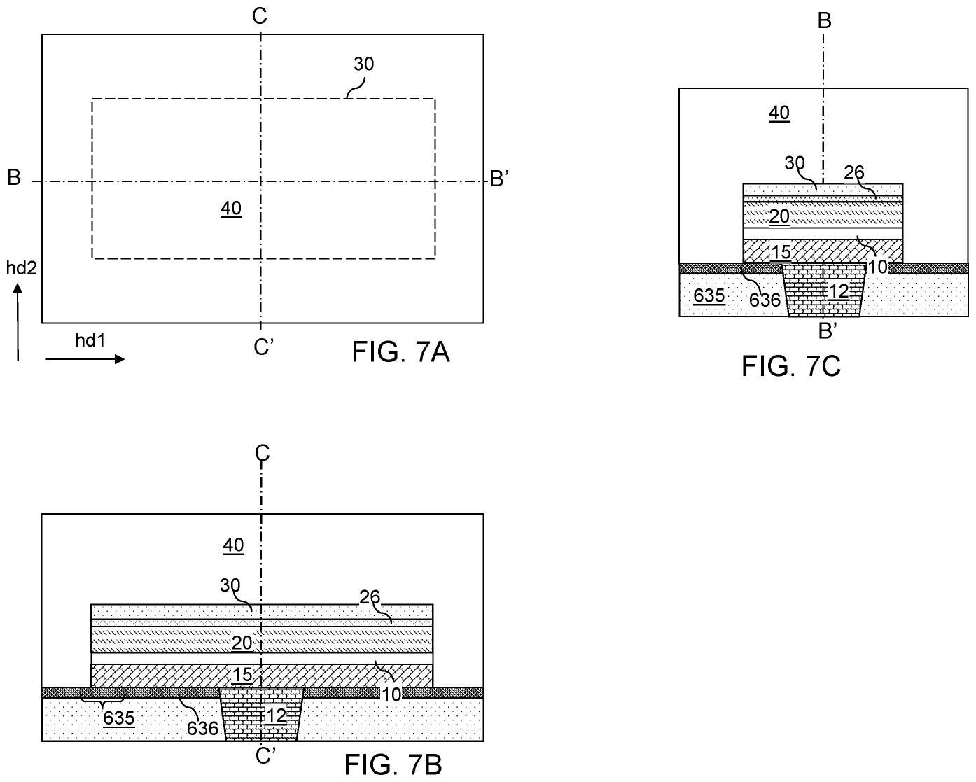

Referring to FIGS. 7A-7C, a dielectric material such as undoped silicate glass, a doped silicate glass, or organosilicate glass may be deposited over each stack of a gate electrode 15, a gate dielectric layer 10, an active layer 20, an in-process capping layer 26, and an insulating cap layer 30 to form a dielectric material layer 40. The dielectric material layer 40 may be deposited by a self-planarizing deposition method (such as spin-on coating) or may be planarized after deposition (for example, by performing a chemical mechanical polishing process). The vertical distance between the top surface of each insulating cap layer 30 and the top surface of the dielectric material layer 40 may be in a range from 20 nm to 200 nm, although lesser and greater thicknesses may also be used.

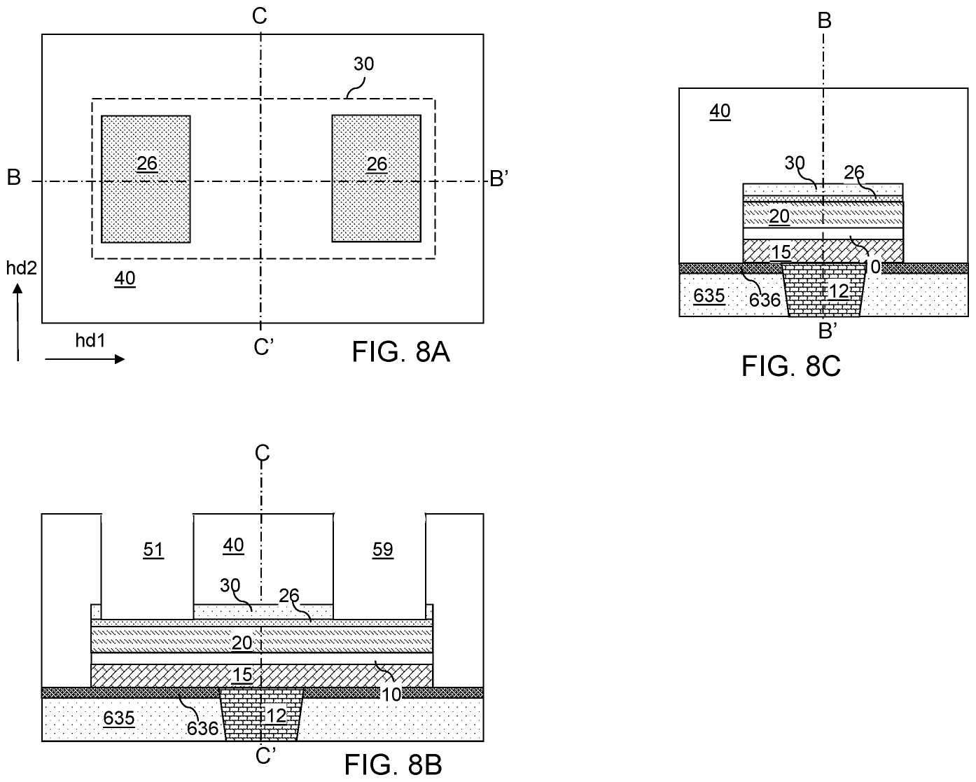

Referring to FIGS. 8A-8C, a photoresist layer (not shown) may be applied over the dielectric material layer 40, and may be lithographically patterned to form discrete openings therein. The pattern of the discrete openings in the photoresist layer may be transferred through the dielectric material layer 40 and the insulating cap layer 30 by an anisotropic etch process to form a source cavity 51 and a drain cavity 59 over each active area 20.

According to an aspect of the present disclosure, the anisotropic etch process may have an etch chemistry that etches the materials of the dielectric material layer 40 and the insulating cap layer 30 selective to the material of the in-process capping layer 26. In other words, the anisotropic etch process may etch the materials of the dielectric material layer 40 and the insulating cap layer 30 without etching the material of the in-process capping layer 26. In this embodiment, the in-process capping layer 26 functions as an etch stop layer for the anisotropic etch process. Portions of the in-process capping layer 26 may be physically exposed at the bottom of the source cavity 51 and at the bottom of the drain cavity 59. The top surface of the active layer 20 can be covered by the in-process capping layer 26. The in-process capping layer 26 may have a uniform thickness throughout.

The lateral spacing between the bottom periphery of the source cavity 51 and the bottom periphery of the drain cavity 59 defines the channel length of the transistor (e.g., TFT) to be subsequently formed. The channel length may be in a range from 1 nm to 100 nm, such as from 2 nm to 50 nm, although lesser and greater channel lengths may also be used. The in-process capping layer 26 protects the active layer 20 from plasma damage. Thus, the defect density of the semiconducting metal oxide material in the active layer 20 does not increase due to the anisotropic etch process that forms the source cavity 51 and the drain cavity 59. Further, the dielectric metal oxide material of the in-process capping layer 26 provides a reduced interface defect density Dit at the interface with the insulating cap layer 30 relative to a hypothetical structure in which the active layer 20 directly contacts the insulating cap layer 30. For example, the in-process capping layer 26 has an interfacial trap density that is less than 5×10¹¹/(cm²×eV) at an interface with an overlying insulating material, i.e., at an interface with the insulating cap layer 30.

The in-process capping layer 26 may function as an etch stop layer during formation of the source cavity 51 and the drain cavity 59. The collateral etching of the material of the in-process capping layer 26 during the anisotropic etch process that forms the source cavity 51 and the drain cavity 59 is preferably minimal. In one embodiment, the thickness of the remaining portion of the in-process capping layer 26 underlying the source cavity 51 or the drain cavity 59 can be greater than 30%, and preferably greater than 50%, and even more preferably greater than 70%, and/or greater than 80%, and/or greater than 90%, and/or greater than 95%, of the thickness of the in-process capping layer 26 prior to the anisotropic etch process.

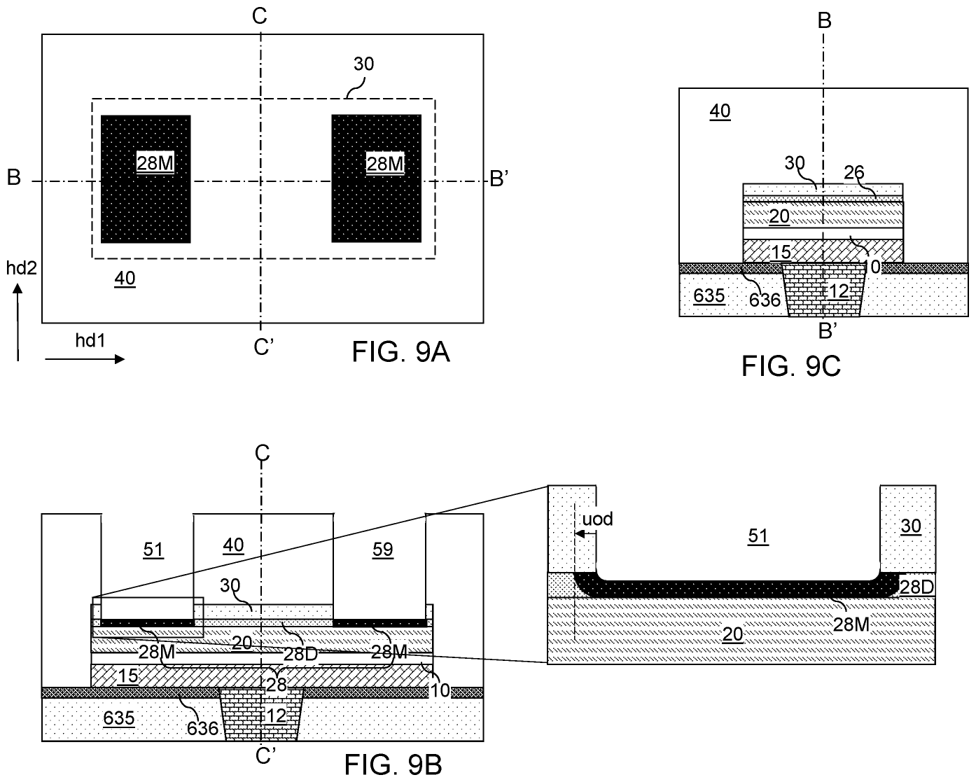

Referring to FIGS. 9A-9C, a region of the first configuration of an embodiment structure is illustrated after formation of a compositionally-modulated capping layer 28. Specifically, a reduction process can be performed on the exposed portions of the in-process capping layer 26. The dielectric metal oxide material within the exposed portions of the in-process capping layer 26 are reduced into at least one metal that is free of oxygen. In other words, the oxygen atoms in the exposed portions of the in-process capping layer 26 are removed during the reduction process, thereby reducing the dielectric metal oxide material of the physically exposed portions of the in-process capping layer 26 into metallic material portions consisting essentially of the at least one metal (as provided in the continuous capping material layer 26L). In one embodiment, the reduction process comprises a hydrogen plasma treatment process. The hydrogen plasma reacts with the oxygen atoms in the in-process capping layer 26 to generate water vapors, which are volatilized and pumped out of the plasma treatment chamber. Atoms of the at least one metal that loses the oxygen atoms coalesce to form metal plates, which comprise the conductive capping material portions 28M.

The plasma intensity and the duration of the hydrogen plasma treatment process may be selected such that each portion of the in-process capping layer 26 having an areal overlap with the source cavity 51 or with the drain cavity 59 in a plan view is converted into a metallic material portion, which is herein referred to as a conductive capping material portion 28M. The conductive caping material portions 28M may have the same material composition as the continuous metal layer 27L. For example, the conductive capping material portion 28M may comprise, and/or may consist essentially of, titanium, barium, tantalum, tungsten, molybdenum, hafnium, yttrium, lanthanum, another transition metal, or an alloy thereof. Each conductive capping material portion 28M may consist essentially of the at least one metal, and may provide sheet resistance less than 100 Ohms per square.

The portion of the in-process capping layer 26 that is not reduced into a metallic material constitutes a dielectric capping material portion 28D. Generally, loss of the oxygen atoms can cause reduction of the thickness in the conductive capping material portion 28M relative to the thickness of the dielectric capping material portion 28D. The thickness of each conductive capping material portion 28M ma be in a range from 40% to 70% of the thickness of the dielectric capping material portion 28D.

Generally, physically exposed portions of the in-process capping layer 26 can be converted into a first conductive capping material portion 28M that underlie the source cavity 51 and into the second conductive capping material portion 28M that underlie the drain cavity 59. The dielectric capping material portion 28D comprises a remaining portion of the dielectric metal oxide material. The combination of the dielectric capping material portion 28D and the conductive capping material portion 28M constitutes a compositionally-modulated capping layer 28. Thus, the in-process capping layer 26 can be converted into the compositionally-modulated capping layer 28.

The compositionally-modulated capping layer 28 overlies the active layer 20, and comprises a first conductive capping material portion 28M, a second conductive capping material portion 28M, and a dielectric capping material portion 28D. The dielectric metal oxide material is an oxide of at least one metal, and the first conductive capping material portion 28M and the second conductive capping material portion 28M comprise, and/or consist essentially of, the at least one metal. In one embodiment, the first conductive capping material portion 28M and the second conductive capping material portion 28M are formed by reduction of the dielectric metal oxide into the at least one metal. The reduction of the dielectric metal oxide into the at least one metal is effected by performing a hydrogen plasma treatment process.

The plasma reduction process reduces the material of the physically exposed portions of the in-process capping layer 26 isotropically. The plasma energy and the duration of the plasma during the plasma reduction process can be selected such that the boundary between the reduced portions of the in-process capping layer 26 (i.e., the conductive capping material portions 28M) and the unreduced portion of the in-process capping layer 26 (i.e., the dielectric capping material portion 28D) shifts by a distance that is greater than the thickness of the in-process capping layer 26. In one embodiment, each sidewall of the source structure 52 and the drain structure 56 comprises a respective bottom periphery that is spaced from a top periphery of a respective conductive capping material portion 28M by a uniform offset distance uod, which is the plasma reduction distance. The plasma reduction distance may be in a range from 100% to 150%, such as from 100% to 120%, of the thickness of the in-process capping layer 26 (which is the same as the thickness of the dielectric capping material portion 28D). Each sidewall of the source cavity 51 and the drain cavity 59 comprises a respective bottom periphery that is spaced from a top periphery of a respective conductive capping material portion 28M by a uniform offset distance uod, which can be the plasma reduction distance.

Generally, the material composition of the conductive capping material portions 28M may be the same as the material composition of the continuous metal layer 27L, and may consist of the at least one metal of the continuous metal layer 27L. If the continuous metal layer 27L comprises at least two metals, the conductive capping material portions 28M may comprise the at least two metals. Each atomic ratio between the at least two metals in the conductive capping material portions 28M may be the same as a respective corresponding atomic ratio between the at least two metals within the continuous metal layer 27L. Furthermore, each atomic ratio between the at least two metals within the dielectric capping material portion 28D equals a corresponding atomic ratio between the at least two metals within the first conductive capping material portion 28M and within the second conductive capping material portion 28M. In one embodiment, the first conductive capping material portion 28M and the second conductive capping material portion 28M may be metal portions that are free of oxygen atoms.

As discussed above, the collateral etching of the material of the in-process capping layer 26 during the anisotropic etch process that forms the source cavity 51 and the drain cavity 59 is preferably minimal. The thickness of the conductive capping material portions 28M is directly proportional to the thickness of the remaining portion of the in-process capping layer 26 underlying the source cavity 51 or the drain cavity 59 after the anisotropic etch process. The areal density of the at least one metal in the conductive capping material portions 28M can be greater than 30%, and preferably greater than 50%, and even more preferably greater than 70%, and/or greater than 80%, and/or greater than 90%, and/or greater than 95%, of the areal density of the at least one metal within the continuous capping material layer 26L as formed at the processing steps of FIGS. 4A-4C. In one embodiment, a first areal density of the at least one metal as obtained by integrating a volume density of the at least one metal along a vertical direction within the first conductive capping material portion 28M is in a range from 30% to 100% (such as from 50% to 90% and/or from 60% to 80%) of a second areal density of the at least one metal as obtained by integrating a volume density of the at least one metal along the vertical direction within the dielectric capping material portion 28D. As used herein, an areal density of an element refers to a value generated by integrating the volume density of the element along a thickness direction (such as a vertical direction).

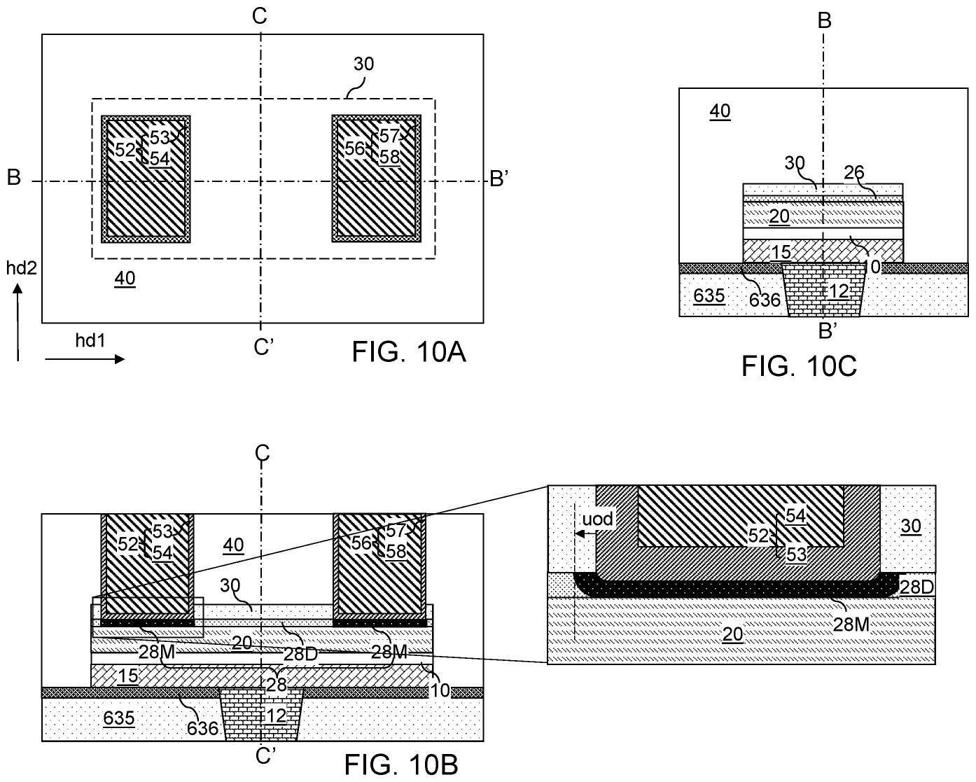

Referring to FIGS. 10A-10C, a region of the first configuration of an embodiment structure is illustrated after formation of a source structure 52 and a drain structure 56. At least one conductive material may be deposited in the source cavity 51 and drain cavity 59 and over the dielectric material layer 40. The at least one conductive material may include a metallic liner material and a metallic fill material. The metallic liner material may include a conductive metallic nitride or a conductive metallic carbide such as TiN, TaN, WN, TiC, TaC, and/or WC. The metallic fill material may include W, Cu, Al, Co, Ru, Mo, Ta, Ti, alloys thereof, and/or combinations thereof. Other suitable metallic liner and metallic fill materials within the contemplated scope of disclosure may also be used.

Excess portions of the at least one conductive material may be removed from above the horizontal plane including the top surface of the dielectric material layer 40 by a planarization process, which may use a chemical mechanical polishing (CMP) process and/or a recess etch process. Other suitable planarization processes may be used. Each remaining portion of the at least one conductive material filling a source cavity 51 constitutes a source structure 52. Each remaining portion of the at least one conductive material filling a drain cavity 59 constitutes a drain structure 56. In one embodiment, the at least one conductive material may comprise a combination of the metallic liner material and the metallic fill material described above.

In one embodiment, each source structure 52 may include a source metallic liner 53 that is a remaining portion of the metallic liner material, and a source metallic fill material portion 54 that is a remaining portion of the metallic fill material. Each drain structure 56 may include a drain metallic liner 57 that is a remaining portion of the metallic liner material, and a drain metallic fill material portion 58 that is a remaining portion of the metallic fill material.

The compositionally-modulated capping layer 28 overlies the active layer 20, and comprises a first conductive capping material portion 28M, a second conductive capping material portion 28M, and a dielectric capping material portion 28D. The insulating cap layer 30 overlies the compositionally-modulated capping layer 28. The dielectric material layer 40 overlies the insulating cap layer 30, and laterally surrounds the source structure 52, the drain structure 56, the active layer 20 located on the gate dielectric layer 10, and the compositionally-modulated capping layer 28.

The source structure 52 may be formed in the source cavity 51, and the drain structure 56 can be in the drain cavity 59. The source structure 52 and the drain structure 56 can be formed on the first conductive capping material portion 28M and the second conductive capping material portion 28M, respectively. The source structure 52 can vertically extend through the dielectric material layer 40 and the insulating cap layer 30, and can contact a top surface of the first conductive capping material portion 28M. The drain structure 56 can vertically extend through the dielectric material layer 40 and the insulating cap layer 30, and can contact a top surface of the second conductive capping material portion 28M. In one embodiment, each sidewall of the source structure 52 and the drain structure 56 comprises a respective bottom periphery that is spaced from a top periphery of a respective conductive capping material portion 28M by a uniform offset distance uod.

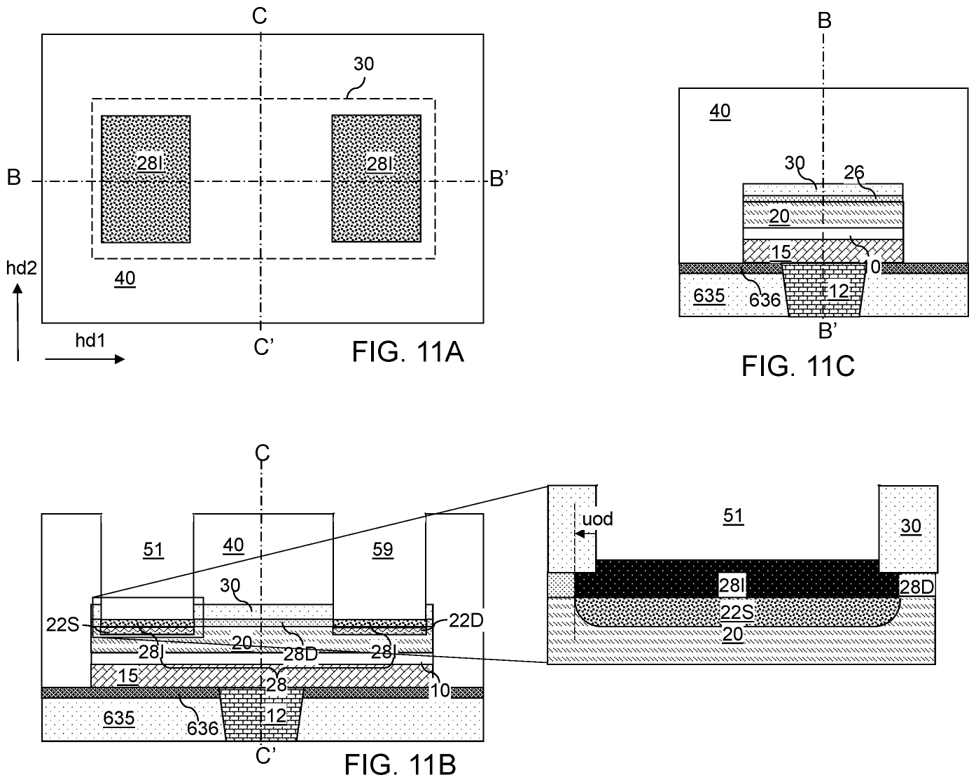

Referring to FIGS. 11A-11C, a second configuration of an embodiment structure is illustrated after formation of conductive capping material portions 28I. The second configuration of the exemplary structure can be derived from the exemplary structure illustrated in FIGS. 8A-8C by performing an ion implantation process that implants atoms of at least one additional metal into the physically exposed portions of the in-process capping layer 26. The at least one additional metal may comprise any transition metal, aluminum, indium, or gallium. The at least one additional metal may, or may not be, the same as one or more of the at least one metal in the in-process capping layer 26. In one embodiment, the at least one additional metal that is implanted into the physically exposed portions of the in-process capping layer 26 may be different from each of the at least one metal in the in-process capping layer 26. In one embodiment, the at least one additional metal may comprise one or more transition metal elements exhibiting low diffusivity, such as refractory metal elements (e.g., tungsten, niobium, molybdenum, tantalum, and rhenium).

The exposed portions of the in-process capping layer 26 can be converted not into metal-rich metal oxide material portions by introducing atoms of the at least one additional metal into the exposed portions of the in-process capping layer 26. The atoms of the at least one additional metal can be introduced into the in-process capping layer 26 by performing an ion implantation process. According to an aspect of the present disclosure, the energy of the ions of the at least one additional metal can be selected such that a predominant fraction (i.e., more than 50%) of the implanted ions are implanted into the physically exposed portions of the in-process capping layer 26. Further, the dose of the implanted ions can be selected such that the metal-rich metal oxide material portions become conductive. The conductive metal-rich metal oxide material portions are herein referred to as conductive capping material portions 28I.

The oxygen deficiency ratio of conductive capping material portions 28I can be defined as the ratio of a first number to a second number, the first number being the number of additional oxygen atoms that would be desired to convert the material of the conductive capping material portions 28I into a stoichiometric dielectric metal oxide material, and the second number being the total number of oxygen atoms in the stoichiometric dielectric metal oxide material. The oxygen deficiency ratio of conductive capping material portions 28I may be in a range from 0.1 to 0.8, such as from 0.15 to 0.6 and/or from 0.2 to 0.5 and/or from 0.25 to 0.4.

Generally, the physically exposed portions of the in-process capping layer 26 can be converted into conductive material portions that include a first conductive capping material portion 28I underlying the source cavity 51 and a second conductive capping material portion 28I underlying the drain cavity 59. The portion of the in-process capping layer 26 that is not implanted with the atoms of the at least one additional metal is herein referred to as a dielectric capping material portion 28D. In one embodiment, the dielectric metal oxide material of the dielectric capping material portion 28D is an oxide of at least one metal, and the first conductive capping material portion 28I and the second conductive capping material portion 28I comprise the at least one metal in the dielectric metal oxide material, and further comprises atoms of the at least one additional metal that is introduced by the ion implantation process. In one embodiment, the first conductive capping material portion 28I and the second conductive capping material portion 28I can be conductive non-stoichiometric metal oxide portions, and can be formed by implantation of atoms of the at least one additional metal that is different from the at least one metal.

In one embodiment, the energy of the ion implantation can be selected such that the atomic concentration of the at least one additional metal in the first conductive capping material portion 28I and the second conductive capping material portion 28I decreases with a vertical distance downward from a horizontal plane including a top surface of the first conductive capping material portion 28I and a top surface of the second conductive capping material portions 28I. In one embodiment, the implanted atoms of the at least one additional metal generally increases the thickness of the implanted portions of the in-process capping layer 26. In one embodiment, the dose of the ion implantation process can be selected such that the conductive capping material portions 28I have a thickness that is greater than the thickness of the dielectric capping material portion 28D.

The first conductive capping material portion 28I and a top surface of the second conductive capping material portions 28I comprise atoms of the at least one metal that is present within the dielectric capping material portion 28D. In one embodiment, a fraction of the implanted ions of the at least one additional metal can be lodged in portions of the active layer 20 that are proximal to the conductive capping material portions 28I, and render the implanted portions of the active layer non-stoichiometric, i.e., metal-rich due to the presence of atoms of the at least one additional metal. In this embodiment, a source-side metal-rich metal oxide region 22S can be formed underneath the first conductive capping material portion 28I that underlies the source cavity 51, and a drain-side metal-rich metal oxide region 22D can be formed underneath the second conductive capping material portion 28I that underlies the drain cavity 59. The thickness of the source-side metal-rich metal oxide region 22S and the drain-side metal-rich metal oxide region 22D may be in a range from 0.1 nm to 2 nm, such as from 0.2 nm to 1 nm. In one embodiment, the atomic concentration of atoms of the at least one additional metal may decrease with a downward distance from a horizontal plane including the top surfaces of the conductive capping material portions 28I.

As discussed above, the collateral etching of the material of the in-process capping layer 26 during the anisotropic etch process that forms the source cavity 51 and the drain cavity 59 is preferably minimal. The thickness of the conductive capping material portions 28I is generally proportional to the thickness of the remaining portion of the in-process capping layer 26 underlying the source cavity 51 or the drain cavity 59 after the anisotropic etch process. The areal density of the at least one metal in the conductive capping material portions 28I can be greater than 30%, and preferably greater than 50%, and even more preferably greater than 70%, and/or greater than 80%, and/or greater than 90%, and/or greater than 95%, of the areal density of the at least one metal within the continuous capping material layer 26L as formed at the processing steps of FIGS. 4A-4C. In one embodiment, a first areal density of the at least one metal as obtained by integrating a volume density of the at least one metal along a vertical direction within the first conductive capping material portion 28I is in a range from 30% to 100% (such as from 50% to 90% and/or from 60% to 80%) of a second areal density of the at least one metal as obtained by integrating a volume density of the at least one metal along the vertical direction within the dielectric capping material portion 28D.

In one embodiment, the number of implanted metal atoms in the conductive capping material portions 28I may be greater than the number of pre-exiting metal atoms as provided in the physically exposed portions of the in-process capping layer 26. In this embodiment, an areal density of the at least one metal as obtained by integrating a density of the at least one metal along a vertical direction within the first conductive capping material portion 28I (or within the second conductive capping material portion 28I) may be less than a total areal density of the at least one additional metal as obtained by integrating a volume density of the at least one additional metal along the vertical direction within the first conductive capping material portion 28I (or within the second conductive capping material portion 28I). In some embodiments, the oxygen deficiency ratio of conductive capping material portions 28I may be in a range from 0.5 to 0.8.

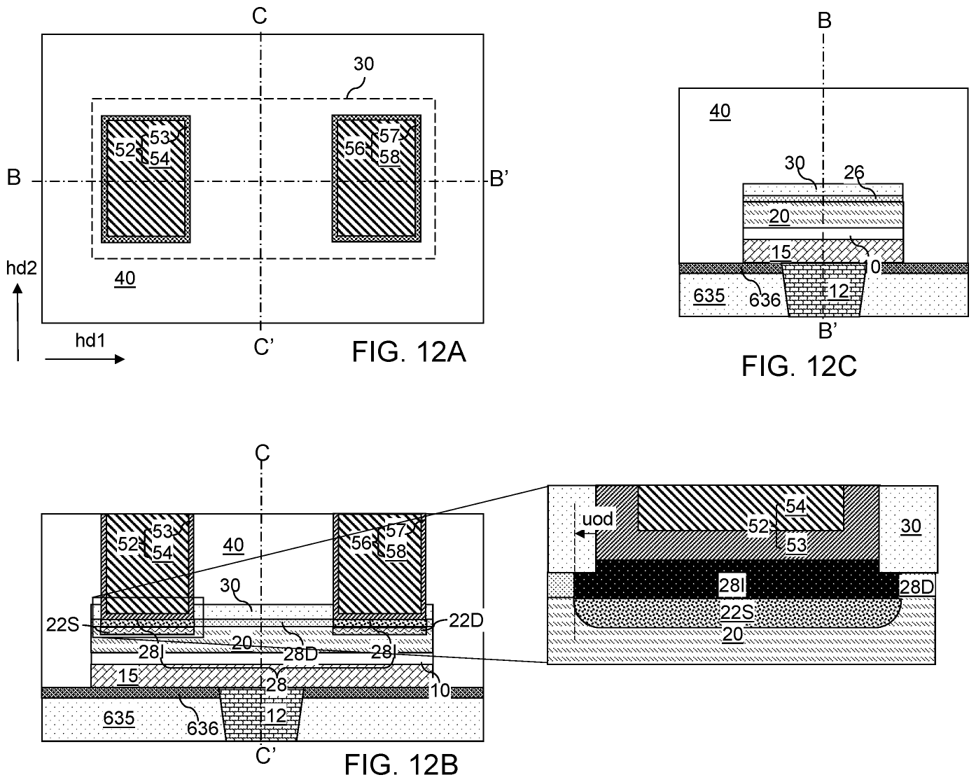

Referring to FIGS. 12A-12C, a region of the second configuration of the exemplary structure is illustrated after formation of a source structure 52 and a drain structure 56. Generally, the processing steps described with reference to FIGS. 10A-10C can be performed to form the source structure 52 and the drain structure 56. In one embodiment, each source structure 52 may include a source metallic liner 53 and a source metallic fill material portion 54. Each drain structure 56 may include a drain metallic liner 57 and a drain metallic fill material portion 58.

The compositionally-modulated capping layer 28 overlies the active layer 20, and comprises a first conductive capping material portion 28I, a second conductive capping material portion 28I, and a dielectric capping material portion 28D. The insulating cap layer 30 overlies the compositionally-modulated capping layer 28. The dielectric material layer 40 overlies the insulating cap layer 30, and laterally surrounds the source structure 52, the drain structure 56, the active layer 20 located on the gate dielectric layer 10, and the compositionally-modulated capping layer 28.

The source structure 52 can be formed in the source cavity, and the drain structure 56 can be in the drain cavity. The source structure 52 and the drain structure 56 can be formed on the first conductive capping material portion 28I and the second conductive capping material portion 28I, respectively. The source structure 52 can vertically extend through the dielectric material layer 40 and the insulating cap layer 30, and can contact a top surface of the first conductive capping material portion 28I. The drain structure 56 can vertically extend through the dielectric material layer 40 and the insulating cap layer 30, and can contact a top surface of the second conductive capping material portion 28I. In one embodiment, each sidewall of the source structure 52 and the drain structure 56 comprises a respective bottom periphery that is spaced from a top periphery of a respective conductive capping material portion 28I by a uniform offset distance uod.

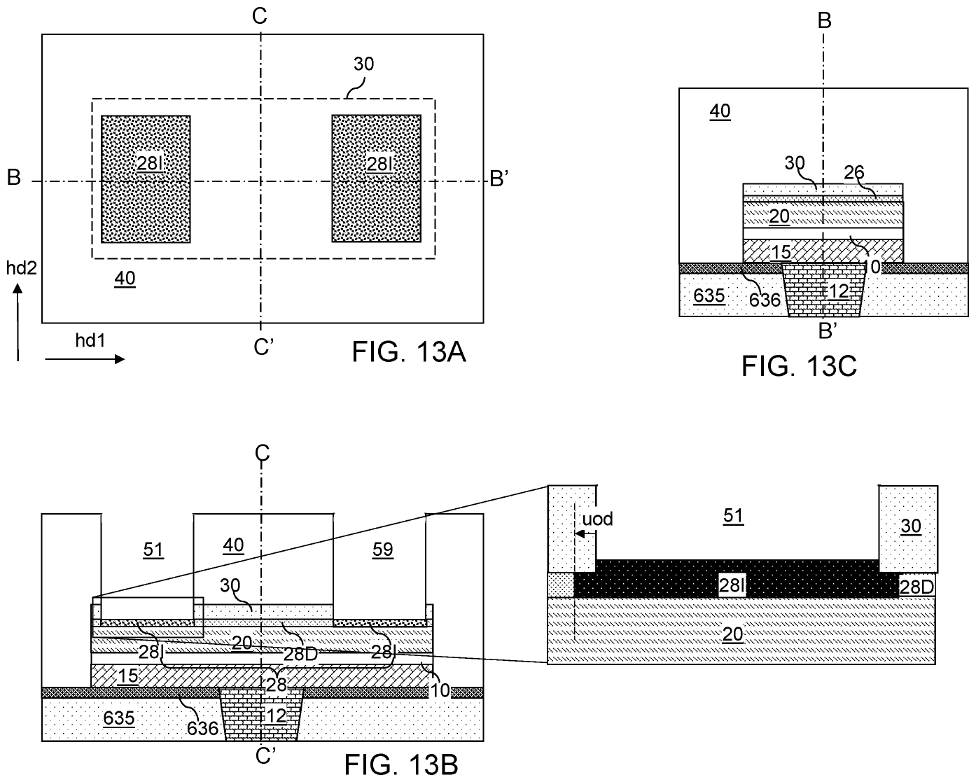

Referring to FIGS. 13A-13C, a third configuration of an embodiment structure is illustrated after formation of conductive capping material portions 28I according to an embodiment of the present disclosure. The third configuration of the exemplary structure can be derived from the second configuration of the exemplary structure by adjusting the energy of the ion implantation process that is performed to implant atoms of the at least one additional metal. Specifically, the energy of the ion implantation process can be lowered such that the implanted ions do not enter the active layer 20. In this embodiment, the source-side metal-rich metal oxide region 22S and the drain-side metal-rich metal oxide region 22D are not formed in the third configuration of the exemplary structure. The conductive capping material portions 28I can be in direct contact with the top surface of the active layer 20. Generally, the third configuration of the exemplary structure can have the same structural and compositional features as the second configuration of the exemplary structure except the presence of the source-side metal-rich metal oxide region 22S and the drain-side metal-rich metal oxide region 22D.

The atomic concentration of the at least one additional metal in the first conductive capping material portion 28I and the second conductive capping material portion 28I decreases with a vertical distance downward from a horizontal plane including a top surface of the first conductive capping material portion 28I and a top surface of the second conductive capping material portions 28I. In one embodiment, the implanted atoms of the at least one additional metal generally increases the thickness of the implanted portions of the in-process capping layer 26. In one embodiment, the dose of the ion implantation process can be selected such that the conductive capping material portions 28I have a thickness that is greater than the thickness of the dielectric capping material portion 28D.

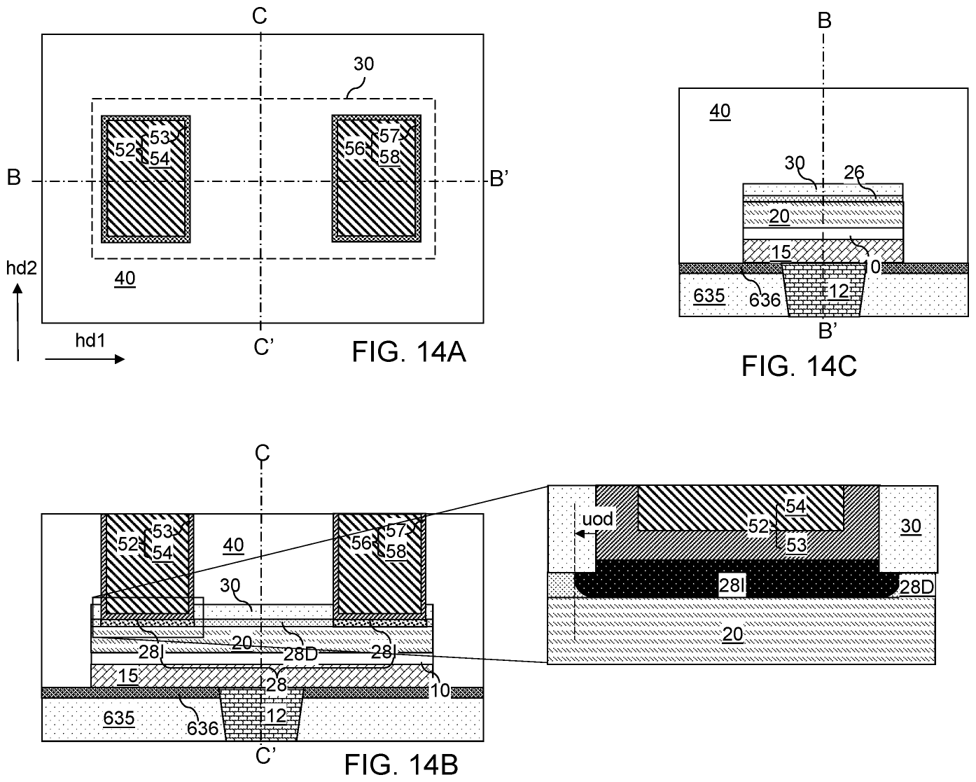

Referring to FIGS. 14A-14C, a region of the third configuration of an embodiment structure is illustrated after formation of a source structure 52 and a drain structure 56. Generally, the processing steps described with reference to FIGS. 10A-10C can be performed to form the source structure 52 and the drain structure 56. In one embodiment, each source structure 52 may include a source metallic liner 53 and a source metallic fill material portion 54. Each drain structure 56 may include a drain metallic liner 57 and a drain metallic fill material portion 58.

The compositionally-modulated capping layer 28 overlies the active layer 20, and comprises a first conductive capping material portion 28I, a second conductive capping material portion 28I, and a dielectric capping material portion 28D. The insulating cap layer 30 overlies the compositionally-modulated capping layer 28. The dielectric material layer 40 overlies the insulating cap layer 30, and laterally surrounds the source structure 52, the drain structure 56, the active layer 20 located on the gate dielectric layer 10, and the compositionally-modulated capping layer 28.

The source structure 52 can be formed in the source cavity, and the drain structure 56 can be in the drain cavity. The source structure 52 and the drain structure 56 can be formed on the first conductive capping material portion 28I and the second conductive capping material portion 28I, respectively. The source structure 52 can vertically extend through the dielectric material layer 40 and the insulating cap layer 30, and can contact a top surface of the first conductive capping material portion 28I. The drain structure 56 can vertically extend through the dielectric material layer 40 and the insulating cap layer 30, and can contact a top surface of the second conductive capping material portion 28I. In one embodiment, each sidewall of the source structure 52 and the drain structure 56 comprises a respective bottom periphery that is spaced from a top periphery of a respective conductive capping material portion 28I by a uniform offset distance uod.

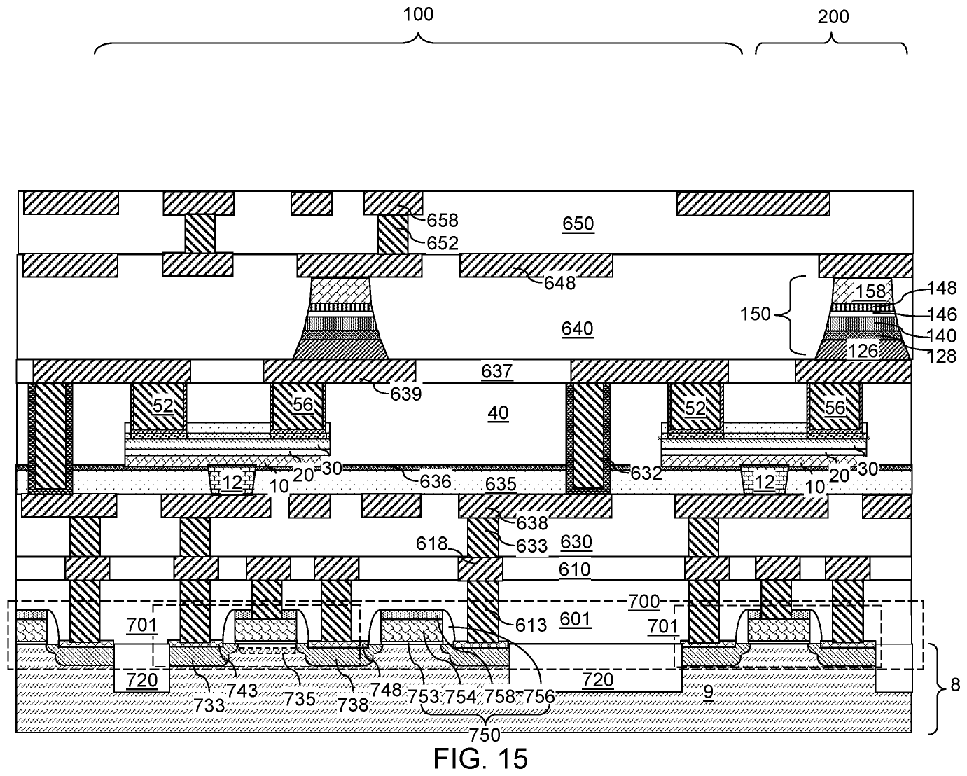

Referring to FIG. 15, the embodiment structure is illustrated after performing additional processing steps. The embodiment structure illustrated in FIG. 15 may be derived from any configuration of the embodiment structure illustrated in FIGS. 10A-10C, 12A-12C, or 14A-14C by subsequently forming additional structures thereupon. In some embodiments, second metal via structures 632 may be formed through the dielectric material layer 40 and the insulating material layer 635 on a respective one of the third metal line structures 639 concurrent with, before, or after, formation of the source structures 52 and the drain structures 56.

A dielectric layer, which is herein referred to as a third line-level dielectric layer 637, may be deposited over the dielectric material layer 40. Third metal line structures 639 may be formed in the third line-level dielectric layer 637 on a respective one of the metallic structures (52, 56, 632) embedded within the dielectric material layer 40.

Additional metal interconnect structures embedded in additional dielectric layers may be subsequently formed over the transistors, such as thin film transistors, and the third line-level dielectric layer 637. In an illustrative example, the dielectric layers may include, for example, a fourth interconnect-level dielectric layer 640, a fifth interconnect-level dielectric layer 650, etc. The additional metal interconnect structures may include third metal via structures (not illustrated) and fourth metal lines 648 embedded in the fourth interconnect-level dielectric layer 640, fourth metal via structures 652 and fifth metal line structures 658 embedded in the fifth interconnect-level dielectric layer 650, etc.

Optionally, memory cells 150 may be formed below, above, or at the same level as, the transistors. In embodiments in which the transistors are formed as a two-dimensional periodic array, the memory cells 150 may be formed as a two-dimensional periodic array of memory cells 150. Each memory cell 150 may include a magnetic tunnel junction, a ferroelectric tunnel junction, a phase change memory material, or a vacancy-modulated conductive oxide material portion. Further, each memory cell 150 may include a first electrode 126 including a metallic material, and a second electrode 158 including a metallic material and protecting an underlying data-storing portion of the memory cell 150. A memory element is provided between the first electrode 126 (i.e., the bottom electrode) and the second electrode 158 (i.e., the top electrode).

In an illustrative example, in embodiments in which the memory cell 150 includes a magnetic tunnel junction, the memory cell 150 may include a layer stack including, from bottom to top, a first electrode 126, a metallic seed layer 128 that facilitates crystalline growth of overlying material layers, a synthetic antiferromagnet (SAF) structure 140, a tunneling barrier layer 146, a free magnetization layer 148, and a second electrode 158. While the present disclosure is described using an embodiment in which the transistors, such as thin film transistors, are used as access transistors for memory cells 150, embodiments are expressly contemplated herein in which the transistors are used as logic devices, as components of a peripheral circuit for a memory array, or for any other semiconductor circuitry.

In one embodiment, the substrate 8 may include a single crystalline silicon substrate. Lower-level dielectric layers (601, 610, 630) embedding lower-level metal interconnect structures (613, 618, 633, 638) may be located between the single crystalline silicon substrate and the insulating layer 635. Field effect transistors 701 including a respective portion of the single crystalline silicon substrate as a channel may be embedded within the lower-level dielectric layers (601, 610, 630), and may be electrically connected to at least one of the gate electrodes 15, the source structures 52, and the drain structures 56.

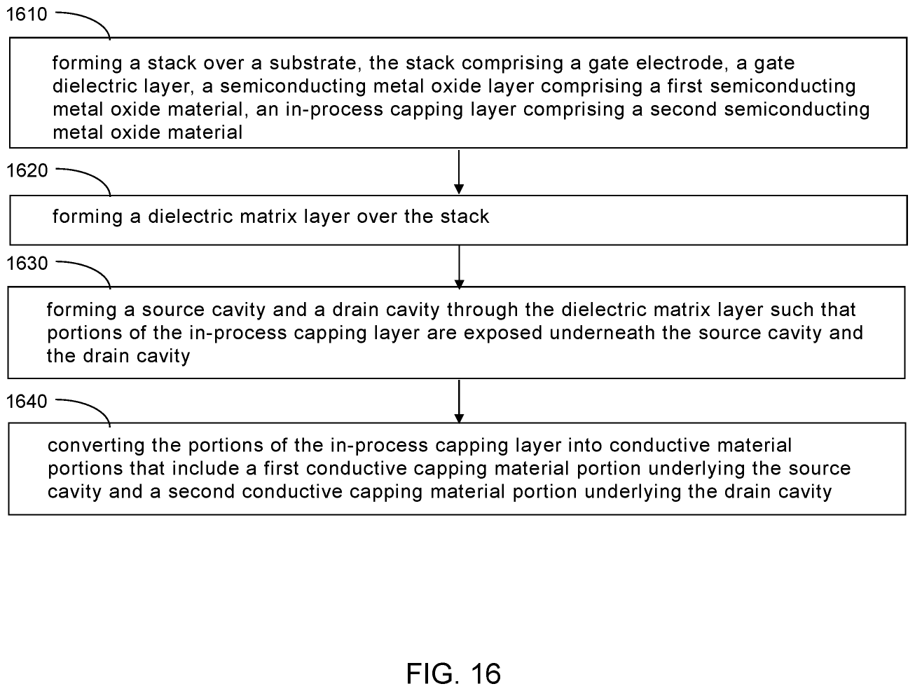

Referring to FIG. 16, a first flowchart illustrates the general processing steps for manufacturing the semiconductor devices of the present disclosure.

Referring to step 1610 and FIGS. 1-6C, a stack can be formed over a substrate 8. The stack comprises a gate electrode 15, a gate dielectric layer 10, an active layer 20 comprising a semiconducting metal oxide material, an in-process capping layer 26 comprising a dielectric metal oxide material.

Referring to step 1620 and FIGS. 7A-7C, a dielectric material layer 40 can be formed over the stack.

Referring to step 1630 and FIGS. 8A-8C, a source cavity 51 and a drain cavity 59 can be formed through the dielectric material layer 40 such that portions of the in-process capping layer 26 are exposed underneath the source cavity 51 and the drain cavity 59.

Referring to step 1640 and FIGS. 9A-14, the portions of the in-process capping layer 26 can be converted into conductive material portions that include a first conductive capping material portion (28M, 28I) underlying the source cavity 51 and a second conductive capping material portion (28M, 28I) underlying the drain cavity 59.

In one embodiment, the method may further comprise: forming a source structure 52 in the source cavity 51; and forming a drain structure 56 in the drain cavity 59. In one embodiment, the method may further comprise performing a reduction process after on the exposed portions of the in-process capping layer 26, whereby the dielectric metal oxide material within the portions of the in-process capping layer 26 are reduced into at least one metal that is free of oxygen. In one embodiment, the reduction process comprises a hydrogen plasma treatment process.

In one embodiment, the method further comprises converting the exposed portions of the in-process capping layer 26 into metal-rich metal oxide material portions by introducing atoms of at least one metal into the exposed portions of the in-process capping layer 26. In one embodiment, the atoms of the at least one metal are introduced into the in-process capping layer 26 by performing an ion implantation process.

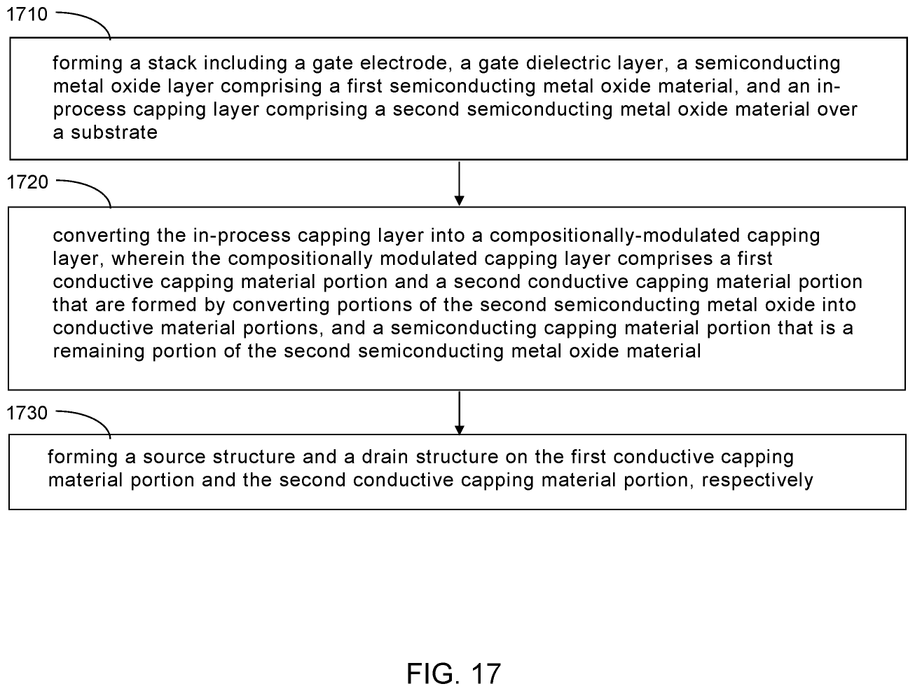

Referring to FIG. 17, a second flowchart illustrates the general processing steps for manufacturing the semiconductor devices of the present disclosure.

Referring to step 1710 and FIGS. 1-6C, a stack comprising a gate electrode 15, a gate dielectric layer 10, an active layer 20 comprising a semiconducting metal oxide material, and an in-process capping layer 26 comprising a dielectric metal oxide material can be formed over a substrate 8.

Referring to step 1720 and FIGS. 7A-9C, 11A-11C, and 13A-13C, the in-process capping layer 26 can be converted into a compositionally-modulated capping layer 28. The compositionally modulated capping layer comprises a first conductive capping material portion (28M, 28I) and a second conductive capping material portion (28M, 28I) that are formed by converting portions of the dielectric metal oxide into conductive material portions, and a dielectric capping material portion 28D that is a remaining portion of the dielectric metal oxide material.

Referring to step 1730 and FIGS. 10A-10C, 12A-12C, 14A-14C, and 15, a source structure 52 and a drain structure 56 can be formed on the first conductive capping material portion (28M, 28I) and the second conductive capping material portion (28M, 28I), respectively.

In one embodiment, the method further comprises: forming a dielectric material layer 40 over the stack; and forming a source cavity 51 and drain cavity 59 through the dielectric material layer 40, wherein the portions of the dielectric metal oxide that are subsequently converted into conductive material portions are exposed underneath the source cavity 51 and the drain cavity 59. In one embodiment, the source structure 52 is formed in the source cavity 51; and the drain structure 56 is formed in the drain cavity 59. In one embodiment, the stack comprises an insulating cap layer 30 overlying the in-process capping layer 26; and the source cavity 51 and the drain cavity 59 are formed by performing an anisotropic etch chemistry that etches materials of the dielectric material layer 40 and the insulating cap layer 30 selective to the dielectric metal oxide.

In one embodiment, the dielectric metal oxide material is an oxide of at least one metal; and the first conductive capping material portion (28M, 28I) and the second conductive capping material portion (28M, 28I) comprise the at least one metal. In one embodiment, the first conductive capping material portion 28M and the second conductive capping material portion 28M consist essentially of the at least one metal. In one embodiment, the first conductive capping material portion 28M and the second conductive capping material portion 28M are formed by reduction of the dielectric metal oxide into the at least one metal. In one embodiment, the reduction of the dielectric metal oxide into the at least one metal is effected by performing a hydrogen plasma treatment process.

In one embodiment, the first conductive capping material portion 28I and the second conductive capping material portion 28I are non-stoichiometric metal oxide portions. In one embodiment, the first conductive capping material portion 28I and the second conductive capping material portion 28I are formed by implantation of atoms of at least one additional metal that is different from the at least one metal. In one embodiment, an atomic concentration of the at least one additional metal in the first conductive capping material portion 28I decreases with a vertical distance downward from a horizontal plane including a top surface of the first conductive capping material portion 28I.

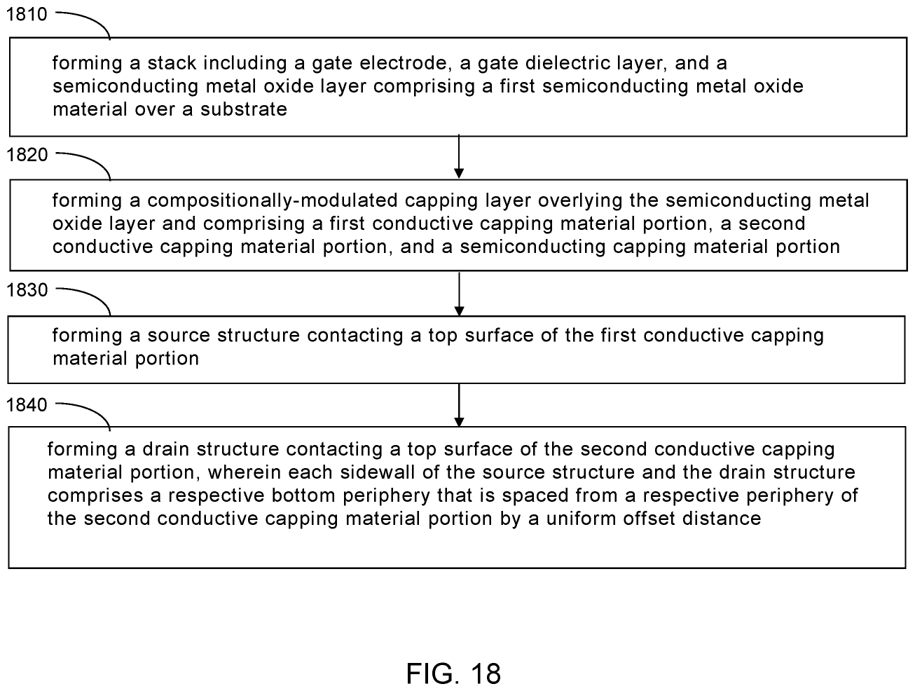

Referring to FIG. 18, a third flowchart illustrates the general processing steps for manufacturing the semiconductor devices of the present disclosure.

Referring to step 1810 and FIGS. 1-6C, a stack including a gate electrode 15, a gate dielectric layer 10, and an active layer 20 comprising a semiconducting metal oxide material can be formed over a substrate 8.

Referring to step 1820 and FIGS. 7A-9C, 11A-11C, and 13A-13C, a compositionally-modulated capping layer 28 overlying the active layer 20 and comprising a first conductive capping material portion (28M, 28I), a second conductive capping material portion (28M, 28I), and a dielectric capping material portion 28D can be formed.

Referring to step 1830 and FIGS. 10A-10C, 12A-12C, 14A-14C, and 15, a source structure 52 contacting a top surface of the first conductive capping material portion (28M, 28I) can be formed.

Referring to step 1840 and FIGS. 10A-10C, 12A-12C, 14A-14C, and 15, a drain structure 56 contacting a top surface of the second conductive capping material portion (28M, 28I) can be formed. Each sidewall of the source structure 52 and the drain structure 56 comprises a respective bottom periphery that is spaced from a top periphery of a respective conductive capping material portion (28M, 28I) by a uniform offset distance uod.

In one embodiment, the method comprises: forming an in-process capping layer 26 comprising a dielectric metal oxide material over the active layer 20; and converting portions of the in-process capping layer 26 into the first conductive capping material portion (28M, 28I) and the second conductive capping material portion (28M, 28I), wherein the dielectric capping material portion 28D comprises a remaining portion of the dielectric metal oxide material. In one embodiment, the active layer 20 comprises a semiconducting metal oxide material having a first enthalpy of oxide formation; the dielectric capping material portion 28D comprises a dielectric metal oxide material having a second enthalpy of oxide formation that is higher the first enthalpy of oxide formation; and the dielectric capping material portion provides an interfacial trap density that is less than 5×10¹¹/(cm²×eV) at an interface with an overlying insulating material.

Referring to all drawings and according to various aspects of the present disclosure, a semiconductor structure including a field effect transistor is provided. The field effect transistor comprises: a gate electrode 15 located over a substrate 8; a gate dielectric layer 10 located on the gate electrode 15; an active layer 20 located on the gate dielectric layer 10; a compositionally-modulated capping layer 28 overlying the active layer 20 and comprising a first conductive capping material portion (28M, 28I), a second conductive capping material portion (28M, 28I), and a dielectric capping material portion 28D; a dielectric material layer 40 overlying the compositionally-modulated capping layer 28; a source structure 52 vertically extending through the dielectric material layer 40 and contacting a top surface of the first conductive capping material portion (28M, 28I); and a drain structure 56 vertically extending through the dielectric material layer 40 and contacting a top surface of the second conductive capping material portion (28M, 28I).

In one embodiment, the dielectric capping material portion 28D comprise a dielectric metal oxide material that is an oxide of at least one metal; and the first conductive capping material portion (28M, 28I) and the second conductive capping material portion (28M, 28I) comprise the at least one metal. In one embodiment, a first areal density of the at least one metal as obtained by integrating a volume density of the at least one metal along a vertical direction within the first conductive capping material portion (28M, 28I) is in a range from 30% to 100% (such as from 50% to 90% and/or from 60% to 80%) of a second areal density of the at least one metal as obtained by integrating a volume density of the at least one metal along the vertical direction within the dielectric capping material portion 28D. In one embodiment, the at least one metal comprises at least two metals; and each atomic ratio between the at least two metals within the dielectric capping material portion 28D equals a corresponding atomic ratio between the at least two metals within the first conductive capping material portion (28M, 28I). In one embodiment, the first conductive capping material portion 28M and the second conductive capping material portion 28M are metal portions that are free of oxygen atoms. In one embodiment, the first conductive capping material portion 28M and the second conductive capping material portion 28M consist of the at least one metal.

In one embodiment, the first conductive capping material portion 28I and the second conductive capping material portion 28I are non-stoichiometric metal oxide portions. In one embodiment, the first conductive capping material portion 28I and the second conductive capping material portion 28I comprises at least one additional metal that is different from the at least one metal. In one embodiment, an areal density of the at least one metal as obtained by integrating a density of the at least one metal along a vertical direction within the first conductive capping material portion 28I is less than a total areal density of the at least one additional metal as obtained by integrating a volume density of the at least one additional metal along the vertical direction within the first conductive capping material portion 28I.

In one embodiment, the active layer 20 comprises a semiconducting metal oxide material having a first enthalpy of oxide formation; and the dielectric capping material portion 28D comprises a dielectric metal oxide material having a second enthalpy of oxide formation that is higher the first enthalpy of oxide formation. In one embodiment, the dielectric capping material portion provides an interfacial trap density that is less than 5×10¹¹/(cm²×eV) at an interface with an overlying insulating material.

According to another aspect of the present disclosure, a semiconductor structure including a field effect transistor is provided. The field effect transistor comprises: a gate electrode 15 located over a substrate 8; a gate dielectric layer 10 located on the gate electrode 15; an active layer 20 located on the gate dielectric layer 10; a compositionally-modulated capping layer 28 overlying the active layer 20 and comprising a first conductive capping material portion (28M, 28I), a second conductive capping material portion (28M, 28I), and a dielectric capping material portion 28D; a source structure 52 contacting a top surface of the first conductive capping material portion (28M, 28I); and a drain structure 56 contacting a top surface of the second conductive capping material portion (28M, 28I), wherein each sidewall of the source structure 52 and the drain structure 56 comprises a respective bottom periphery that is spaced from a top periphery of a respective conductive capping material portion (28M, 28I) by a uniform offset distance uod.

In one embodiment, the semiconductor structure comprises: an insulating cap layer 30 overlying the compositionally-modulated capping layer 28; and a dielectric material layer 40 overlying the insulating cap layer 30 and laterally surrounding the source structure 52, the drain structure 56, the active layer 20 located on the gate dielectric layer 10, and the compositionally-modulated capping layer 28. In one embodiment, the dielectric capping material portion 28D comprise a dielectric metal oxide material that is an oxide of at least one metal; and the first conductive capping material portion (28M, 28I) and the second conductive capping material portion (28M, 28I) comprise the at least one metal.

According to yet another aspect of the present disclosure, a semiconductor structure including a field effect transistor is provided. The field effect transistor comprises: a gate electrode 15 located over a substrate 8; a gate dielectric layer 10 located on the gate electrode 15; an active layer 20 located on the gate dielectric layer 10 and comprising a semiconducting metal oxide material; a compositionally-modulated capping layer 28 overlying the active layer 20 and comprising a first conductive capping material portion (28M, 28I), a second conductive capping material portion (28M, 28I), and a dielectric capping material portion 28D comprising a dielectric metal oxide material that is an oxide of at least one metal; a source structure 52 contacting a top surface of the first conductive capping material portion (28M, 28I); and a drain structure 56 contacting a top surface of the second conductive capping material portion (28M, 28I), wherein: the first conductive capping material portion (28M, 28I) and the second conductive capping material portion (28M, 28I) comprise the at least one metal; and a first areal density of the at least one metal as obtained by integrating a volume density of the at least one metal along a vertical direction within the first conductive capping material portion (28M, 28I) is in a range from 30% to 100% (such as from 50% to 90% and/or from 60% to 80%) of a second areal density of the at least one metal as obtained by integrating a volume density of the at least one metal along the vertical direction within the dielectric capping material portion 28D.

In one embodiment, the semiconductor structure comprises a dielectric material layer 40 overlying the compositionally-modulated capping layer 28 and laterally surrounding the source structure 52 and the drain structure 56. In one embodiment, the at least one metal comprises at least two metals; and each atomic ratio between the at least two metals within the dielectric capping material portion 28D equals a corresponding atomic ratio between the at least two metals within the first conductive capping material portion (28M, 28I).

In one embodiment, the first conductive capping material portion 28M and the second conductive capping material portion 28M are metal portions that are free of oxygen atoms. In one embodiment, the first conductive capping material portion 28M and the second conductive capping material portion 28M consist of the at least one metal. In one embodiment, the first conductive capping material portion 28I and the second conductive capping material portion 28I are non-stoichiometric metal oxide portions which comprises at least one additional metal that is different from the at least one metal.

The various embodiments of the present disclosure can be used to provide thin film transistors that reduces the short channel effect in the backside channel region by reducing the interface defect density, while providing reduced contact resistance between an active layer 20 and each of source structure 52 and the drain structure 56. The thin film transistors of the present disclosure may be integrated in a same semiconductor structure with various additional types of semiconductor devices, non-limiting examples of which include MOSFETs, FinFETs, sensor devices, various cache memory devices, and MEMS devices.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure including a field effect transistor, the field effect transistor comprising:
a gate electrode located over a substrate;
a gate dielectric layer located on the gate electrode;
an active layer located on the gate dielectric layer;
a compositionally-modulated capping layer overlying the active layer, wherein the compositionally-modulated capping layer comprises:
a first conductive capping material portion;
a second conductive capping material portion; and
a dielectric capping material portion;
a dielectric material layer overlying the compositionally-modulated capping layer;
a source structure vertically extending through the dielectric material layer and contacting a top surface of the first conductive capping material portion; and
a drain structure vertically extending through the dielectric material layer and contacting a top surface of the second conductive capping material portion.

2. The semiconductor structure of claim 1, wherein:
the dielectric capping material portion comprise a dielectric metal oxide material that is an oxide of at least one metal; and
the first conductive capping material portion and the second conductive capping material portion comprise the at least one metal.

3. The semiconductor structure of claim 2, wherein a first areal density of the at least one metal as obtained by integrating a volume density of the at least one metal along a vertical direction within the first conductive capping material portion is in a range from 30% to 100% of a second areal density of the at least one metal as obtained by integrating a volume density of the at least one metal along the vertical direction within the dielectric capping material portion.

4. The semiconductor structure of claim 2, wherein:
the at least one metal comprises at least two metals; and
each atomic ratio between the at least two metals within the dielectric capping material portion equals a corresponding atomic ratio between the at least two metals within the first conductive capping material portion.

5. The semiconductor structure of claim 2, wherein the first conductive capping material portion and the second conductive capping material portion are metal portions that are free of oxygen atoms.

6. The semiconductor structure of claim 2, wherein the first conductive capping material portion and the second conductive capping material portion consist of the at least one metal.

7. The semiconductor structure of claim 2, wherein the first conductive capping material portion and the second conductive capping material portion are non-stoichiometric metal oxide portions.

8. The semiconductor structure of claim 2, wherein the first conductive capping material portion and the second conductive capping material portion comprises at least one additional metal that is different from the at least one metal.

9. The semiconductor structure of claim 8, wherein an areal density of the at least one metal as obtained by integrating a density of the at least one metal along a vertical direction within the first conductive capping material portion is less than a total areal density of the at least one additional metal as obtained by integrating a volume density of the at least one additional metal along the vertical direction within the first conductive capping material portion.

10. The semiconductor structure of claim 1, wherein:
the active layer comprises a semiconducting metal oxide material having a first enthalpy of oxide formation; and
the dielectric capping material portion comprises a dielectric metal oxide material having a second enthalpy of oxide formation that is higher the first enthalpy of oxide formation.

11. The semiconductor structure of claim 10, wherein the dielectric capping material portion provides an interfacial trap density that is less than 5×10¹¹/(cm²×eV) at an interface with an overlying insulating material.

12. A semiconductor structure including a field effect transistor, the field effect transistor comprising:
a gate electrode located over a substrate;
a gate dielectric layer located on the gate electrode;
an active layer located on the gate dielectric layer;
a compositionally-modulated capping layer overlying the active layer, wherein the compositionally-modulated capping layer comprises:
a first conductive capping material portion;
a second conductive capping material portion; and
a dielectric capping material portion;
a source structure contacting a top surface of the first conductive capping material portion; and
a drain structure contacting a top surface of the second conductive capping material portion,
wherein each sidewall of the source structure and the drain structure comprises a respective bottom periphery that is spaced from a top periphery of a respective conductive capping material portion by a uniform offset distance.

13. The semiconductor structure of claim 12, further comprising:
an insulating cap layer overlying the compositionally-modulated capping layer; and
a dielectric material layer overlying the insulating cap layer and laterally surrounding the source structure, the drain structure, the active layer located on the gate dielectric layer, and the compositionally-modulated capping layer.

14. The semiconductor structure of claim 12, wherein:
the dielectric capping material portion comprise a dielectric metal oxide material that is an oxide of at least one metal; and
the first conductive capping material portion and the second conductive capping material portion comprise the at least one metal.

15. A method of forming a semiconductor structure, the method comprising:
forming a stack over a substrate, the stack comprising a gate electrode, a gate dielectric layer, an active layer comprising a semiconducting metal oxide material, an in-process capping layer comprising a dielectric metal oxide material;
forming a dielectric material layer over the stack;
forming a source cavity and a drain cavity through the dielectric material layer such that portions of the in-process capping layer are exposed underneath the source cavity and the drain cavity; and
converting the portions of the in-process capping layer into conductive material portions that include a first conductive capping material portion underlying the source cavity and a second conductive capping material portion underlying the drain cavity.

16. The method of claim 15, further comprising:
forming a source structure in the source cavity; and
forming a drain structure in the drain cavity.

17. The method of claim 15, further comprising performing a reduction process on the exposed portions of the in-process capping layer, whereby the dielectric metal oxide material within the portions of the in-process capping layer are reduced into at least one metal that is free of oxygen.

18. The method of claim 17, wherein the reduction process comprises a hydrogen plasma treatment process.

19. The method of claim 15, further comprising converting the exposed portions of the in-process capping layer into metal-rich metal oxide material portions by introducing atoms of at least one metal into the exposed portions of the in-process capping layer.

20. The method of claim 19, wherein the atoms of the at least one metal are introduced into the in-process capping layer by performing an ion implantation process.
